(19) United States
(12) Patent Application Publication
(10) Pub. No.: US 2025/0372530 A1
(43) Pub. Date: Dec. 4, 2025

(54) MARK STRUCTURE FOR NANOSTRUCTURE DEVICE AND METHODS OF FORMING THE SAME

(71) Applicant: Taiwan Semiconductor Manufacturing Co., Ltd., Hsinchu (TW)

(72) Inventors: Chia-Chu Liu, Shin-chu city (TW); Li-Kai Lin, Hsinchu (TW)

(21) Appl. No.: 18/796,839

(22) Filed: Aug. 7, 2024

Related U.S. Application Data
(60) Provisional application No. 63/655,143, filed on Jun. 3, 2024.

(51) Int. Cl. H01L 23/544; H01L 21/8234; H01L 27/088; H01L 29/06; H01L 29/423; H01L 29/66; H01L 29/775; H01L 29/786

(52) U.S. Cl. CPC H01L 23/544; H10D 30/014; H10D 30/43; H10D 30/6735; H10D 30/6757; H10D 62/121; H10D 64/017; H10D 84/0128; H10D 84/0151; H10D 84/038; H10D 84/83

(57) ABSTRACT

A method includes forming a first nanostructure stack and a second nanostructure stack over a substrate, wherein the first nanostructure stack and the second nanostructure stack include alternating layers of a first semiconductor material and a second semiconductor material; performing a first etching process, wherein the first etching process removes the first semiconductor material of the first nanostructure stack to form first openings and recesses the first semiconductor material of the second nanostructure stack to form second openings; depositing a first dielectric material in the first openings and on the second semiconductor material in the second openings; performing a second etching process, wherein the second etching process removes the first dielectric material from the first openings, wherein the first dielectric material remains on the second semiconductor material in the second openings after performing the second etching process; and forming gate structures in the first openings.

### PRIORITY CLAIM AND CROSS-REFERENCE

This application claims the benefit of U.S. Provisional Application No. 63/655,143, filed on Jun. 3, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2, 3, 4, 5, 6A, 6B, 7A, 7B, 8A, 8B, 8C, 9A, 9B, 10A, 10B, 11A, 11B, 12A, 12B, 13A, 13B, 14A, 14B, 14C, 14D, 15A, 15B, 15C, 16A, 16B, 16C, 17A, 17B, 17C, 18A, 18B, 18C, 19A, 19B, 19C, 20, 21A, 21B, and 21C illustrate various views of intermediate stages in the manufacturing of nanostructure-FETs, in accordance with some embodiments.

FIG. 22 illustrates a plan view of a wafer comprising mark structures, in accordance with some embodiments.

FIGS. 23, 24, 25, 26, 27, 28, 29, 30, 31, 32, 33, and 34 illustrate various views of intermediate stages in the manufacturing of mark structures, in accordance with some embodiments.

FIGS. 35, 36, 37, 38, 39, 40, and 41 illustrate various views of intermediate stages in the manufacturing of mark structures, in accordance with some embodiments.

FIGS. 42, 43, 44, 45, 46, 47, 48, 49, 50, and 51 illustrate various views of intermediate stages in the manufacturing of mark structures, in accordance with some embodiments.

FIGS. 52, 53, 54, 55, 56, 57, 58, 59, 60, 61, and 62 illustrate various views of intermediate stages in the manufacturing of mark structures, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nanostructure field-effect transistors (e.g., “nanostructure-FETs” or “nano-FETs”). Various embodiments may be applied, however, to dies comprising other types of transistors (e.g., fin field-effect transistors (FinFETs), planar transistors, stacking transistors, or the like) in lieu of or in combination with the nanostructure-FETs.

According to various embodiments, oxide dummy regions are used to fill regions between channel regions of a nanostructure-FET where the gate structures are subsequently formed. The use of oxide dummy regions allows for more selective etches to be used when removing the oxide dummy regions, which can reduce the risk of etch damage to the channel regions or the source/drain regions. These same techniques are used to form mark structures, such as frame marks, alignment marks, or the like. In some cases, the oxide dummy regions are not fully removed during formation of the mark structures, and accordingly the mark structures include portions of the oxide dummy regions.

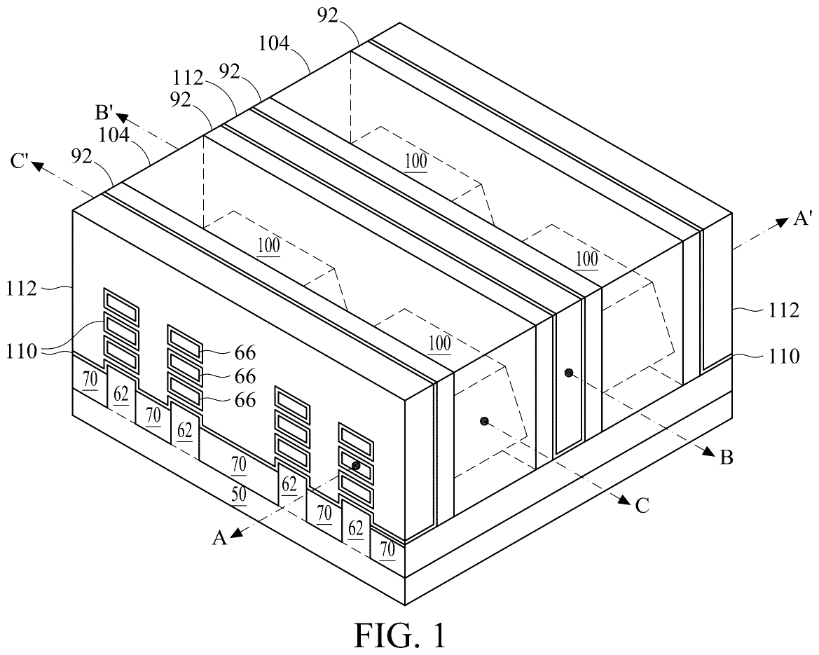

FIG. 1 illustrates an example of nanostructure-FETs (e.g., nanowire FETs, nanosheet FETs, nano-FETs, or the like), gate-all-around (GAA) FETs, or the like) in a three-dimensional view, in accordance with some embodiments. Some features of the nanostructure-FETs may be simplified and/or omitted in FIG. 1 for clarity. The nanostructure-FETs comprise nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. The nanostructures 66 may include p-type nanostructures, n-type nanostructures, or a combination thereof. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Some portions of the isolation regions 70 may be covered by a protective layer or hard mask (not illustrated in FIG. 1). Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portions of the fins 62 and/or the substrate 50 may comprise a single material or a plurality of materials. In this context, the fins 62 refer to the portion extending between the neighboring isolation regions 70.

The gate dielectric layers 110 are over top surfaces of the fins 62 and along top surfaces, sidewalls, and bottom surfaces of the nanostructures 66. Gate electrodes 112 are over the gate dielectric layers 110. The gate dielectric layers 110 and gate electrodes 112 may be collectively be called “gate structures” or “gate stacks.” Source/drain regions 100 (e.g., epitaxial source/drain regions 100) are disposed on the fins 62 at opposing sides of the gate dielectric layers 110 and the gate electrodes 112. Source/drain region(s) 100 may refer to a source or a drain, individually or collectively dependent upon the context. An inter-layer dielectric (ILD) 104 is formed over the source/drain regions 100. Contacts (subsequently described) to the source/drain regions 100 will be formed through the ILD 104. The source/drain regions 100 may be shared between various nanostructures 66. For example, adjacent source/drain regions 100 may be electrically connected, such as through coalescing or merging the source/drain regions 100 by epitaxial growth, or through coupling the source/drain regions 100 with a same contact.

FIG. 1 further illustrates reference cross-sections that are used in later figures. Cross-section A-A′ is along a longitudinal axis of a fin 62 of a nanostructure-FET and in a direction of, for example, a current flow between the source/drain regions 100 of the nanostructure-FET. Cross-section B-B′ is perpendicular to cross-section A-A′ and extends along a longitudinal axis of a gate electrode 112. Cross-section C-C′ is parallel to cross-section B-B′ (e.g., is perpendicular to cross-section A-A′) and extends through source/drain regions 100 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs. Other FETs or configurations of FETs are possible.

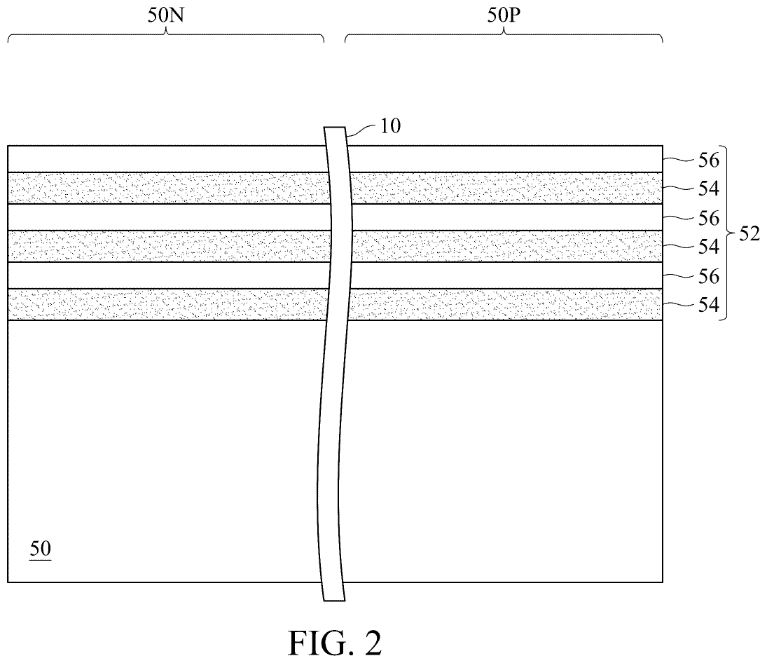

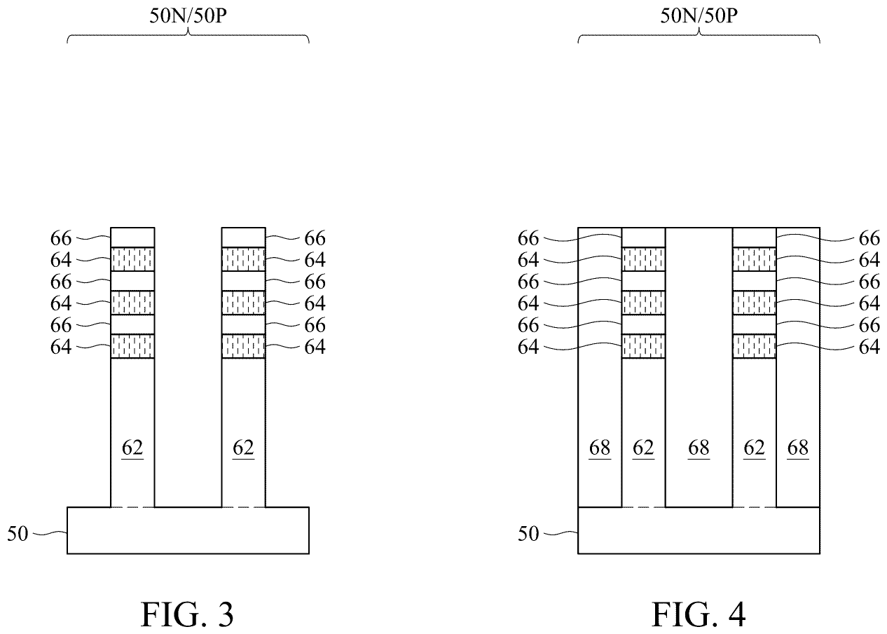

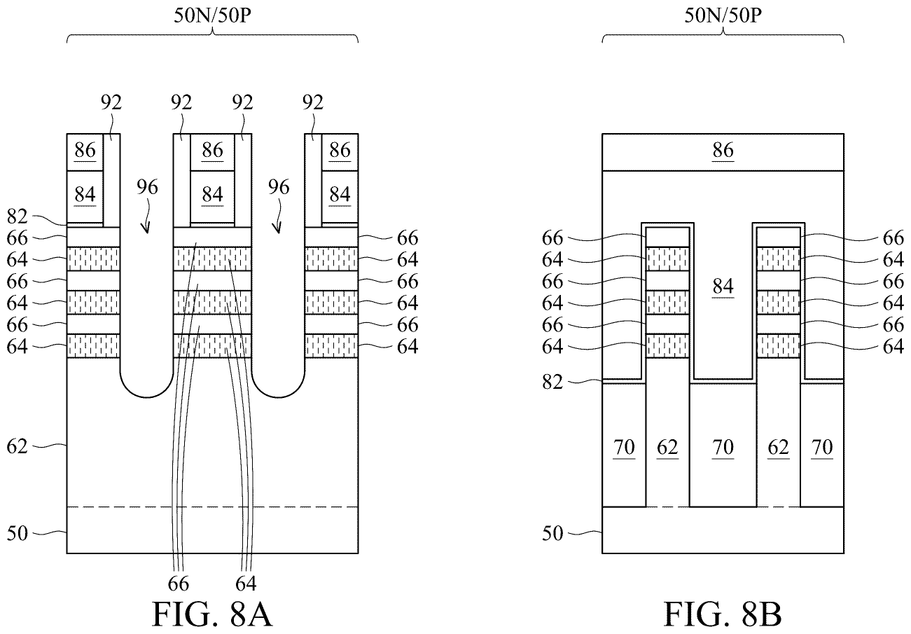

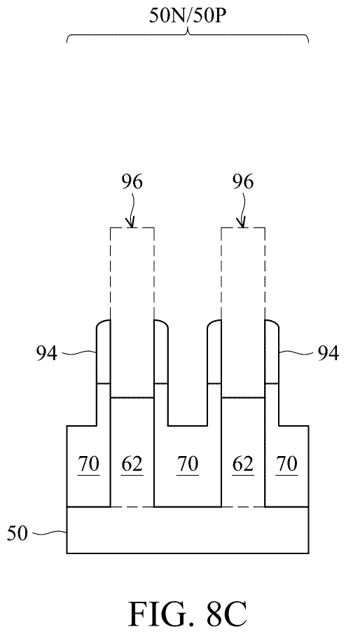

FIGS. 2-21C are views of intermediate stages in the manufacturing of nanostructure-FETs, in accordance with some embodiments. FIGS. 2, 6A, 7A, 8A, 9A, 10A, 11A, 12A, 13A, 13B, 14A, 15A, 16A, 17A, 18A, 19A, 20, and 21A illustrate cross-sectional views along a similar cross-section as reference cross-section A-A′ in FIG. 1. FIGS. 3, 4, 5, 6B, 7B, 8B, 9B, 10B, 11B, 12B, 14B, 15B, 16B, 17B, 18B, 19B, and 21B illustrate cross-sectional views along a similar cross-section as reference cross-section B-B′ in FIG. 1. FIGS. 8C, 14C, 14D, 15C, 16C, 17C, 18C, 19C, and 21C illustrate cross-sectional views along a similar cross-section as reference cross-section C-C′ in FIG. 1.

In FIG. 2, a substrate 50 is provided, in accordance with some embodiments. The substrate 50 may be a semiconductor substrate, such as a bulk semiconductor, a semiconductor-on-insulator (SOI) substrate, or the like, which May be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 52 is formed over the substrate 50, in accordance with some embodiments. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 are patterned to form channel regions for nanostructure-FETs in one region (e.g., the p-type region 50P), and the second semiconductor layers 56 are patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52. For example, the bottom-most second semiconductor layer 56 (e.g., the second semiconductor layer 56 closest to the substrate 50) may be thinner than overlying second semiconductor layers 56 to improve short channel control in the resulting nanostructure-FETs. Other combinations or variations of layer thicknesses are possible.

In FIG. 3, fins 62 are formed in the substrate 50, and first nanostructures 64 and second nanostructures 66 are formed in the multi-layer stack 52, in accordance with some embodiments. The first nanostructures 64 and the second nanostructures 66 may be collectively referred to as the nanostructures 64/66 herein. FIG. 3 may be in either of the n-type region 50N or the p-type region 50P of the substrate 50 unless specifically discussed.

In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56.

The fins 62 and the nanostructures 64/66 may be patterned using any suitable methods. For example, the fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66. Other patterning techniques are possible.

The fins 62 are illustrated as having substantially equal widths in both the n-type region 50N and the p-type region 50P. In other embodiments, a width of the fins 62 in the n-type region 50N may be greater or less than a width of the fins 62 in the p- type region 50P. Further, while each of the fins 62 and the nanostructures 64/66 are illustrated as having a constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

In FIG. 4, an insulation material 68 is formed over the substrate 50 and between adjacent fins 62 and adjacent nanostructures 64/66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64/66. Thereafter, a fill material, such as one of the previously described insulation materials, may be formed over the liner.

The insulation material 68 may be deposited over the fins 62 and nanostructures 64/66 such that excess insulation material 68 covers the nanostructures 64/66. A removal process is then applied to the insulation material 68 to remove excess insulation material 68 over the nanostructures 64/66. In some embodiments, a planarization process such as a chemical mechanical polish (CMP), an etch-back process, combinations thereof, or the like may be utilized. The planarization process may expose the nanostructures 64/66 such that top surfaces of the nanostructures 64/66 and the insulation material 68 are level after the planarization process is complete.

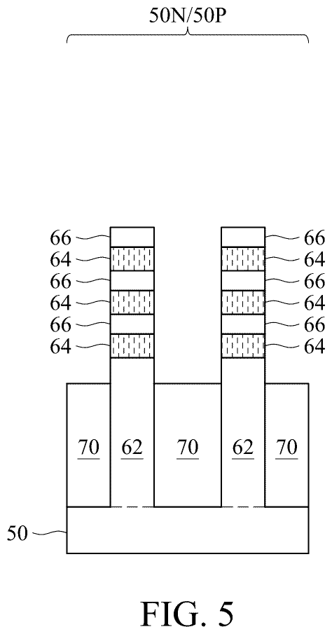

In FIG. 5, the insulation material 68 is recessed to form STI regions 70, in accordance with some embodiments. The STI regions 70 are adjacent to the fins 62. The insulation material 68 is recessed such that upper portions of fins 62 and/or the nanostructures 64/66 protrude from between neighboring STI regions 70. The upper portions of the fins 62 and/or the nanostructures 64/66 are above the STI regions 70. In some cases, portions of the fins 62 and/or the nanostructures 64/66 may be below a top surface of the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric acid (“dHF”) may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further in FIG. 5, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may include phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In other embodiments, a hard mask (not illustrated) may be formed over top surfaces of the STI regions 70. The hard mask may be formed, for example, by first depositing a hard mask material over the nanostructures 64/66, fins 62, and STI regions 70. The hard mask material may be deposited as a continuous layer. Then, the hard mask material is removed from top surfaces and sidewalls of the nanostructures 64/66 and fins 62 using an etching process, with the remaining portions on the STI regions 70 forming the hard mask. In other embodiments, the hard mask material is left remaining on top surfaces of the STI regions 70 and on top surfaces of the nanostructures 64/66, and thus the hard mask is formed on the nanostructures 64/66 in addition to the STI regions 70. The hard mask material may comprise one or more materials that have a high etching selectivity from the etching of the materials of the STI regions 70 and/or the nanostructures 64/66. For example, the hard mask material may comprise a nitride, such as silicon nitride, silicon oxynitride, a silicon oxycarbonitride, a combination thereof, or the like. In some cases, the hard mask material comprises an oxide, such as hafnium oxide, zirconium oxide, or the like. Other materials are possible, and the hard mask material may comprise multiple layers of different materials, in some cases. The hard mask material may be deposited using a suitable process, such as CVD, plasma-enhanced CVD (PECVD), ALD, or the like. The deposition process may be conformal. Portions of the hard mask material may be removed using one or more acceptable etch processes, such as a dry etch, a wet etch, or a combination thereof.

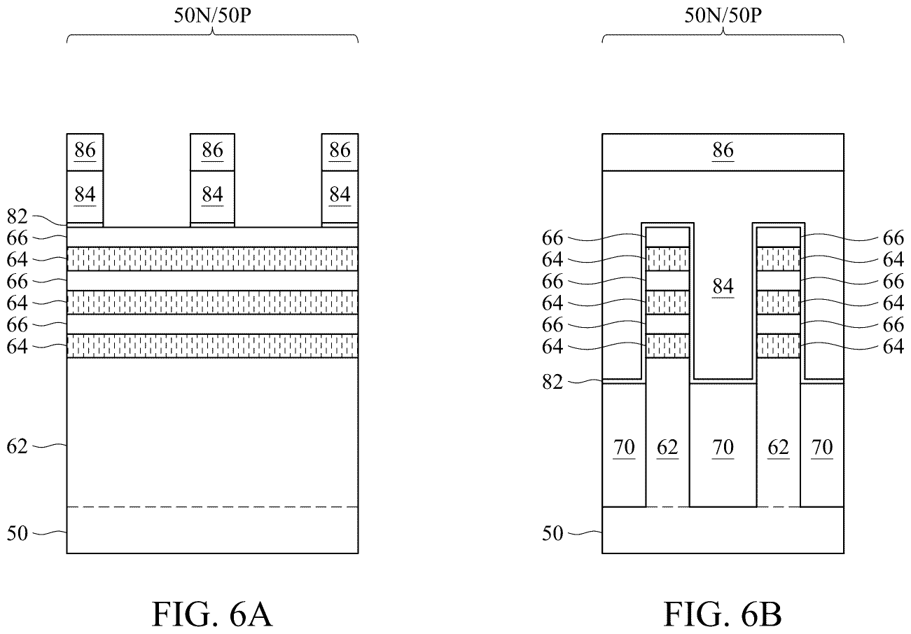

In FIGS. 6A-6B, dummy dielectrics 82, dummy gates 84, and masks 86 are formed over and along sidewalls of the fins 62 and/or the nanostructures 64/66, in accordance with some embodiments. In some embodiments, a dummy dielectric layer is formed on the fins 62 and/or the nanostructures 64/66. The dummy dielectric layer may be formed over the hard mask, if present. The dummy dielectric layer may be formed of silicon oxide, silicon nitride, a combination thereof, or the like, which may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP process or the like. The dummy gate layer may be formed of a conductive or non-conductive material and may be selected from a group including amorphous silicon, polycrystalline-silicon (polysilicon), polycrystalline silicon germanium (poly-SiGe), metallic nitrides, metallic silicides, metallic oxides, and metals. The material of the dummy gate layer may be deposited by CVD, physical vapor deposition (PVD), sputter deposition, or another suitable technique. The dummy gate layer may be formed of other materials that have a high etching selectivity from the etching of insulation materials, e.g., the STI regions 70 and/or the dummy dielectric layer. The mask layer may be deposited over the dummy gate layer. The mask layer may be formed of a dielectric material such as silicon nitride, silicon oxynitride, silicon oxide, or the like.

Subsequently, the mask layer is patterned using acceptable photolithography and etching techniques to form masks 86. The pattern of the masks 86 then may be transferred to the dummy gate layer and to the dummy dielectric layer to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise (e.g., longitudinal) direction of respective fins 62. The masks 86 can optionally be removed after patterning, such as by any acceptable etching technique. In this example, a single dummy gate layer and a single mask layer are formed across the n-type region 50N and the p-type region 50P. In the illustrated embodiment, the dummy dielectric layer covers the STI regions 70, such that the dummy dielectrics 82 extends between the dummy gates 84 and the STI regions 70. In another embodiment, the dummy dielectrics 82 covers only the fins 62 and/or the nanostructures 64/66.

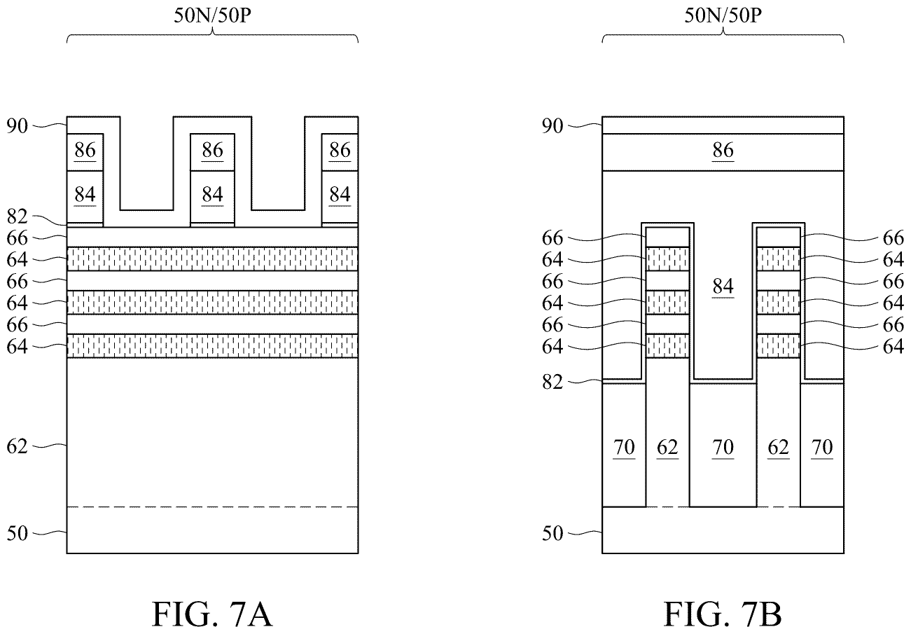

In FIGS. 7A-7B, a spacer layer 90 is conformally formed over the structure, in accordance with some embodiments. The spacer layer 90 is formed over the nanostructures 64/66 and the STI regions 70. The spacer layer 90 is also formed on exposed sidewalls of the masks 86 (if present), the dummy gates 84, the dummy dielectrics 82, the nanostructures 64/66, and/or the fins 62. The spacer layer 90 may be formed of one or more dielectric material(s). FIGS. 7A-7B show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 is subsequently etched to form spacers.

In FIGS. 8A-8C, the spacer layer 90 is patterned to form gate spacers 92 and fin spacers 94, in accordance with some embodiments. Any acceptable etching process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 may have straight sidewalls or may have curved sidewalls. In some embodiments, the STI regions 70 may also be etched when patterning the spacer layer 90. For example, the etching may recess portions the STI regions 70 between fins 62 and/or between gate spacers 92. In various embodiments in which a hard mask is present over the STI regions 70, the etching may stop on the hard mask or may etch through the hard mask, depending on the characteristics of the etching process used. The gate spacers 92 and/or the fin spacers 94 may have straight sidewalls (as illustrated) or may have curved sidewalls (not separately illustrated).

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 8A-8C, source/drain recesses 96 are patterned in the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are lower than the top surfaces of the STI regions 70, as shown in FIG. 8C. In other embodiments, the bottom surfaces of the source/drain recesses 96 are about level with or higher than top surfaces of the STI regions 70. The source/drain recesses 96 may be formed by etching the fins 62, the nanostructures 64/66, and the substrate 50 using anisotropic etching processes, such as RIE, NBE, or the like. In some embodiments, the gate spacers 92 and the dummy gates 84 mask portions of the fins 62, the nanostructures 64/66, the STI regions 70, and/or the substrate 50 during the etching processes used to form the source/drain recesses 96. A single etch process or multiple etch processes may be used to etch each layer of the nanostructures 64/66 and/or the fins 62. Timed etch processes may be used to stop the etching of the source/drain recesses 96 after the source/drain recesses 96 reach a desired depth. The etching may etch the STI regions 70, which may form recesses that extend into the STI regions 70 between gate spacers 92. In other embodiments, the STI regions 70 are not etched. For embodiments in which a hard mask is formed over the STI regions 70, the etching may stop on the hard mask, thin the hard mask, or remove the hard mask, depending on the characteristics of the etching process used.

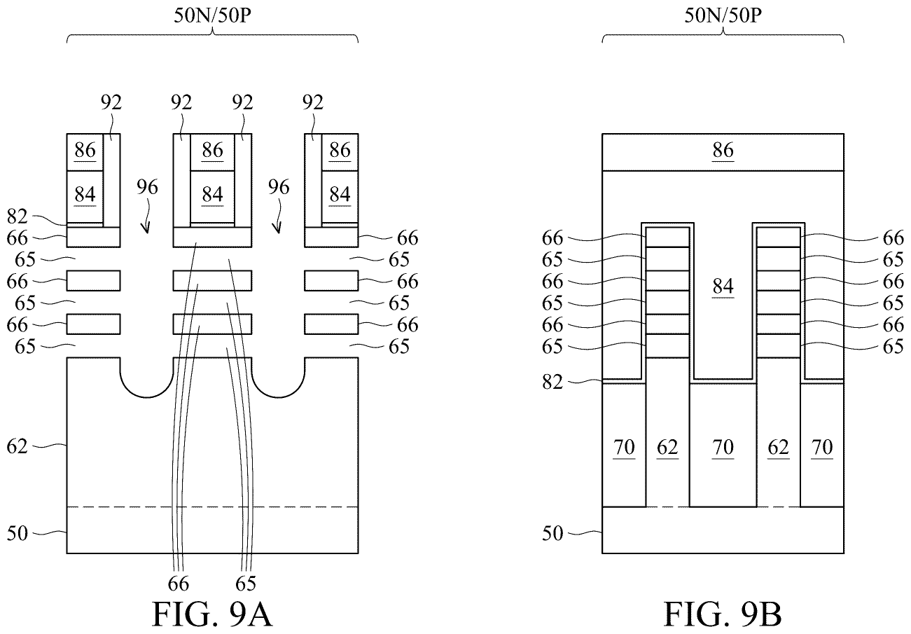

In FIGS. 9A-9B, the remaining portions of the first nanostructures 64 are removed to form openings 65 in regions between the second nanostructures 66, in accordance with some embodiments. The remaining portions of the first nanostructures 64 may be removed using an etching process that is performed through the source/drain recesses 96. The etching process may include any acceptable etching process that selectively etches the material of the first nanostructures 64 at a faster rate than the material of the second nanostructures 66 and the fins 62. The etching process may include a wet etch process and/or a dry etch process, and the etching may isotropic. For example, when the first nanostructures 64 are formed of e.g., silicon germanium and the second nanostructures 66 are formed of e.g., silicon or silicon carbide, the etching process may include a wet etch using tetramethylammonium hydroxide (TMAH), ammonium hydroxide (NH₄OH), or the like. In other embodiments, the etching process may be a dry etch using fluorine (F₂), ammonia (NH₃), hydrofluoric acid (HF), chlorine trifluoride (CIF₃), XeF₃, or the like. In some embodiments, a trim process (not illustrated) is performed to decrease the thicknesses of the exposed portions of the second nanostructures 66 and expand the openings 65. Hereinafter, the second nanostructures 66 may be referred to as nanostructures 66, and the collections of vertically adjacent nanostructures 66 over each fin 62 may be referred to as “stacks” of nanostructures 66.

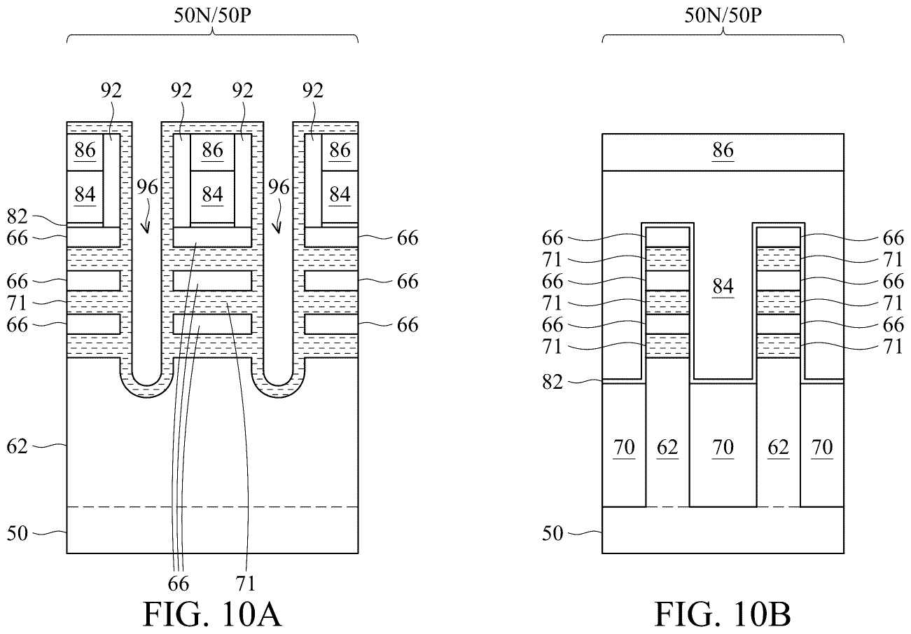

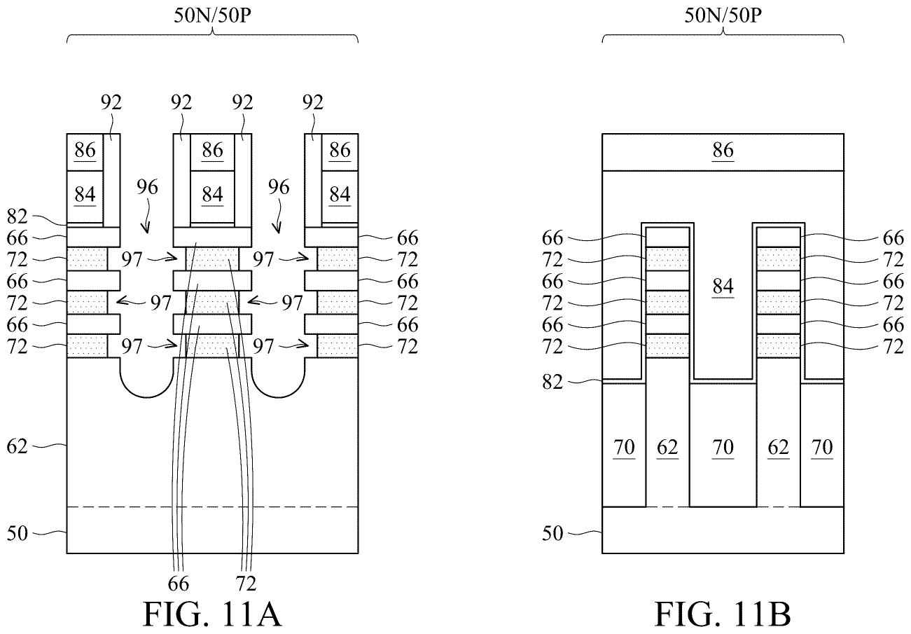

In FIGS. 10A-10B and 11A-11B, the first nanostructures 64 are replaced with a dummy material 71 to form dummy regions 72, in accordance with some embodiments. In some cases, the dummy material 71 may be considered a sacrificial material or a sacrificial oxide. In some cases, the dummy regions 72 may be considered sacrificial regions, dielectric dummy regions, dummy nanostructures, dummy gate regions, or disposable oxide interposers (DOI). Replacing the first nanostructures 64 with dummy regions 72 may provide advantages. For example, in subsequent source/drain formation steps, one or more high temperature processes may be performed to, for example, activate the dopants in the source/drain regions. When the material of the first nanostructures 64 (e.g., silicon germanium or the like) is exposed to high temperatures, germanium intermixing and increased roughness at interfaces between the nanostructures 64 and 66 may result. Such manufacturing defects may degrade the performance of the resulting transistor devices. For example, when germanium diffuses into the second nanostructures 66, germanium residue may remain in channel regions of the resulting transistor devices, which negatively affects the performance of the channel regions. Additionally, the intermixing may result in etching selective to either the first nanostructures 64 or the second nanostructures 66 to be less effective and less defined. This can result in, for example, portions of the second nanostructures 66 being undesirably removed, reducing yield and/or causing performance degradation. By replacing the first nanostructures 64 with an insulating material (e.g., the dummy material 71) prior to the high temperature processes (e.g., source/drain annealing), manufacturing defects can be reduced and device performance can be improved. Additionally, the selectivity of etching between the dummy material 71 and the material of the second nanostructures 66 may be greater than the selectivity of etching between the nanostructures 64 and 66, allowing for improved etching definition and less unwanted etching of the second nanostructures 66.

In FIGS. 10A-10B, a dummy material 71 is deposited in the recesses 96 and in the openings 65, in accordance with some embodiments. The dummy material 71 may be deposited by a conformal deposition process, such as CVD, ALD, or the like. The dummy material 71 may comprise an insulating material such as silicon oxide or the like that can be selectively etched from the nanostructures 66 and the fins 62. As shown in FIGS. 10A-10B, the dummy material 71 may fill or overfill the openings 65 and may cover sidewalls of the nanostructures 66. The dummy material 71 may cover top surfaces of the fins 62. In some embodiments, the dummy material 71 does not completely fill the source/drain recesses 96.

In FIGS. 11A-11B, the dummy material 71 may then be etched to form the dummy regions 72, in accordance with some embodiments. The etching may be isotropic or anisotropic. For example, the dummy material 71 may be etched using a wet etch process, such as dHF or the like. In some embodiments, the etching is performed until sidewalls of the dummy material 71 are recessed past sidewalls of the nanostructures 66, forming sidewall recesses 97. Accordingly, the dummy regions 72 may have a width that is smaller than a width of the nanostructures 66. In some cases, the sidewall recesses 97 may be considered part of the source/drain recesses 96.

Although sidewalls of the dummy regions 72 within the sidewall recesses 97 are illustrated as being flat, the sidewalls may be concave or convex.

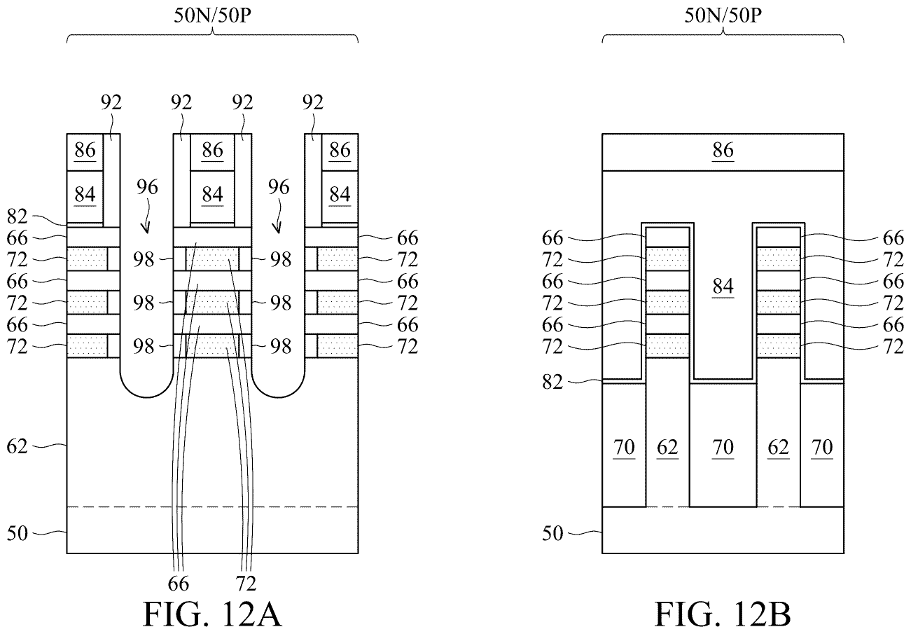

In FIGS. 12A-12B, inner spacers 98 are formed in the sidewall recesses 97, in accordance with some embodiments. In other words, inner spacers 98 are formed on the sidewalls of the dummy regions 72. As will be subsequently described in greater detail, source/drain regions are subsequently formed in the source/drain recesses 96, and the dummy regions 72 are subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes.

In some embodiments, the inner spacers 98 are formed by conformally depositing an insulating material in the source/drain recesses 96 and in the sidewall recesses 97 and subsequently etching the insulating material. The insulating material may be silicon nitride, silicon oxynitride, or the like. However, any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. After performing the etching of the insulating material, the remaining portions of the insulating material within the sidewall recesses 97 form the inner spacers 98. An inner spacer 98 may have a thickness that is smaller than, about the same as, or greater than a thickness of an adjacent dummy region 72.

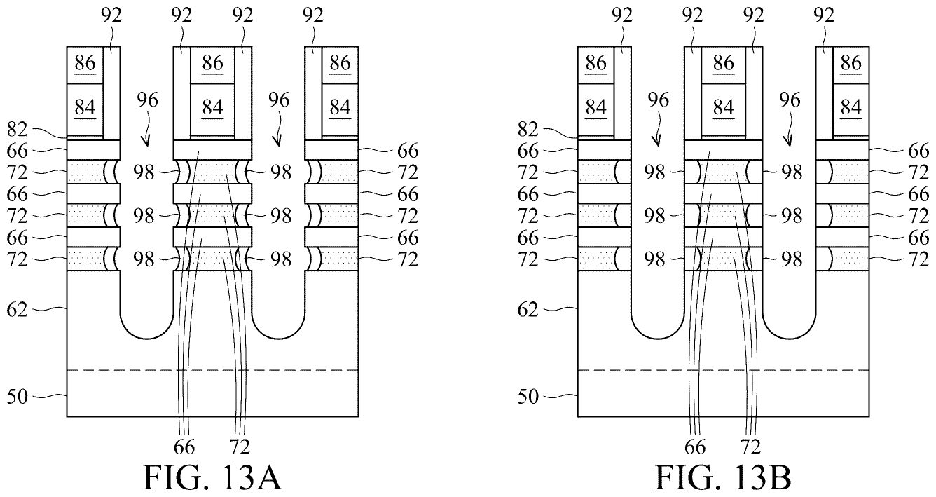

Although outer sidewalls of inner spacers 98 are illustrated as being flush (e.g. approximately coplanar) with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses 97. Moreover, although the sidewalls of the inner spacers 98 are illustrated as being flat in FIGS. 12A-12B, the sidewalls of the inner spacers 98 may be concave or convex. As an example, FIG. 13A illustrates an embodiment in which sidewalls of the dummy regions 72 are concave, outer sidewalls of the inner spacers 98 are concave, and inner spacers 98 are recessed from sidewalls of the nanostructures 66. As another example, FIG. 13B illustrates an embodiment in which sidewalls of the dummy regions 72 are concave, outer sidewalls of the inner spacers 98 are flat, and outer sidewalls of the inner spacers 98 are flush with sidewalls of the nanostructures 66. Other configurations or sidewall profiles are also possible.

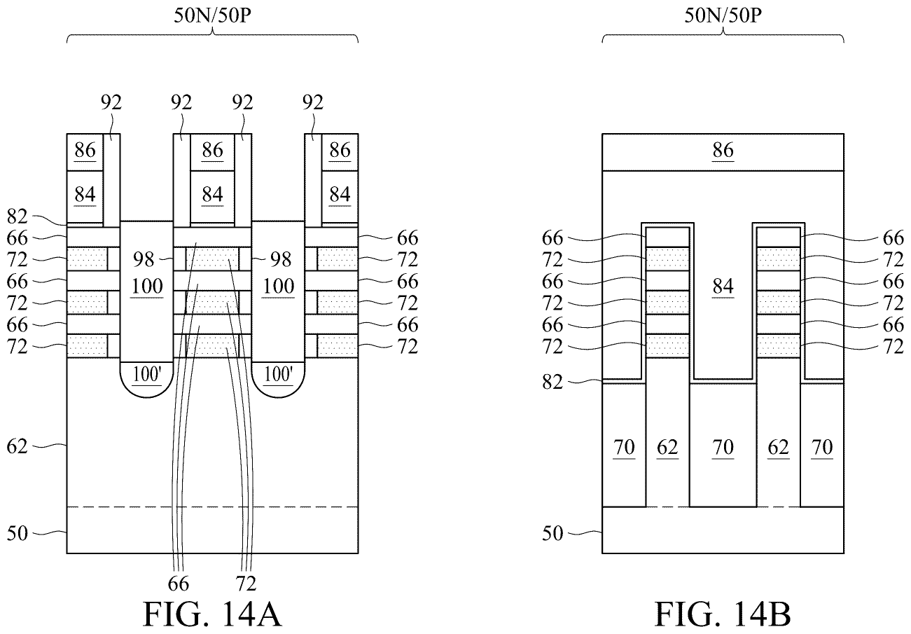

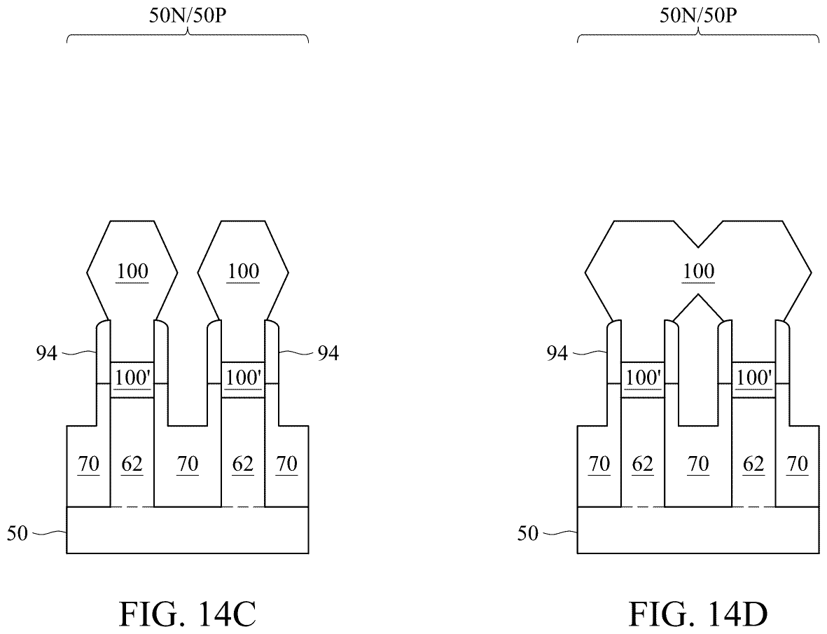

In FIGS. 14A-14D, epitaxial source/drain regions 100 are formed in the source/drain recesses 96 of the n-type region 50N and in the source/drain recesses 96 of the p-type region 50P, in accordance with some embodiments. The epitaxial source/drain regions 100 may also be referred to as “source/drain regions 100.” For example, the epitaxial source/drain regions 100 in the n-type region 50N may be referred to as “n-type source/drain regions,” and the epitaxial source/drain regions 100 in the p-type region 50P may be referred to as “p-type source/drain regions.” The n-type source/drain regions 100 may be formed before, after, or simultaneously with the formation of the p-type source/drain regions 100. The epitaxial source/drain regions 100 may be formed by an epitaxy process, such as such as vapor phase epitaxy (VPE), molecular beam epitaxy (MBE), or the like.

In some embodiments, semiconductor layers 100′ may be formed in the source/drain recesses 96 before forming the epitaxial source/drain regions 100 in the source/drain recesses 96. The semiconductor layers 100′ may comprise, for example, undoped silicon or the like. Although the top surfaces of the semiconductor layers 100′ are illustrated as being flat (e.g., planar), the top surfaces of the semiconductor layers 100′ may be concave or convex. Top surfaces of the semiconductor layers 100′ may be higher than, approximately level with, or below top surfaces of the fins 62. In some embodiments, the semiconductor layers 100′ are not in physical contact with the inner spacers 98. In other embodiments, the semiconductor layers 100′ may be in physical contact with the sidewalls of some inner spacers 98. In some cases, the semiconductor layers 100′ may be considered part of the corresponding epitaxial source/drain regions 100. In other embodiments, an insulating layer (not illustrated) may be deposited in the source/drain recesses 96 before forming the epitaxial source/drain regions 100 in the source/drain recesses 96.

In some embodiments, the epitaxial source/drain regions 100 exert stress on channel regions of the nanostructures 66 within the n-type region 50N and/or within the p-type region 50P, thereby improving performance. The epitaxial source/drain regions 100 are formed in the source/drain recesses 96 such that each dummy gate 84 of the p-type region 50P is disposed between respective neighboring pairs of the epitaxial source/drain regions 100. In some embodiments, the gate spacers 92 are used to separate the epitaxial source/drain regions 100 from the dummy gates 84, and the inner spacers 98 are used to separate the epitaxial source/drain regions 100 from the nanostructures 66 by an appropriate lateral distance such that the epitaxial source/drain regions 100 do not short out with subsequently formed gates of the resulting nanostructure-FETs.

The epitaxial source/drain regions 100 in the n-type region 50N may be formed by masking the p-type region 50P. Then, n-type source/drain regions 100 are epitaxially grown in the source/drain recesses 96 in the n-type region 50N. The n-type source/drain regions 100 may include any acceptable material appropriate for n-type nanostructure-FETs. For example, if the nanostructures 66 are silicon, the n-type source/drain regions 100 may include materials exerting a tensile strain on the nanostructures 66, such as silicon, silicon carbide, phosphorous doped silicon carbide, silicon phosphide, or the like.

The epitaxial source/drain regions 100 in the p-type region 50P may be formed by masking the n-type region 50N. Then, p-type source/drain regions 100 are epitaxially grown in the source/drain recesses 96 in the p-type region 50P. The p-type source/drain regions 100 may include any acceptable material appropriate for p-type nanostructure-FETs. For example, if the nanostructures 66 are silicon, the p-type source/drain regions 100 may include materials exerting a compressive strain on the nanostructures 66, such as silicon germanium, boron doped silicon germanium, germanium, germanium tin, or the like.

The epitaxial source/drain regions 100, nanostructures 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 100 may be in situ doped during growth.

As a result of the epitaxy processes used to form the epitaxial source/drain regions 100 in the n-type region 50N and the p-type region 50P, upper surfaces of the epitaxial source/drain regions 100 have facets which expand laterally outward beyond sidewalls of the nanostructures 66. In some embodiments, adjacent epitaxial source/drain regions 100 remain separated after the epitaxy process is completed, as illustrated by FIG. 14C. In other embodiments, these facets cause adjacent epitaxial source/drain regions 100 of a same nanostructure-FET to merge, as illustrated by FIG. 14D. In the embodiments illustrated in FIGS. 14C and 14D, the fin spacers 94 may be formed on top surfaces of the STI regions 70, thereby blocking epitaxial growth. In some other embodiments, the fin spacers 94 may cover portions of the sidewalls of the nanostructures 66, further blocking the epitaxial growth. In some other embodiments, the spacer etch used to form the fin spacers 94 may be adjusted to remove the spacer material to allow the epitaxially grown region to extend to the surface of the STI regions 70.

The n-type source/drain regions 100 and/or the p-type source/drain regions 100 may comprise one or more semiconductor material layers. Any number of semiconductor material layers may be used for the epitaxial source/drain regions 100. Each semiconductor material layer may be formed of different semiconductor materials and may be doped to different dopant concentrations. In embodiments in which the epitaxial source/drain regions 100 comprise three semiconductor material layers, the first semiconductor material layer may be deposited, the second semiconductor material layer may be deposited over the first semiconductor material layer, and the third semiconductor material layer may be deposited over the second semiconductor material layer. In some embodiments, the first semiconductor material layer may have a dopant concentration less than the second semiconductor material layer and greater than the third semiconductor material layer. Other semiconductor material layers, dopant concentrations, or configurations thereof are possible.

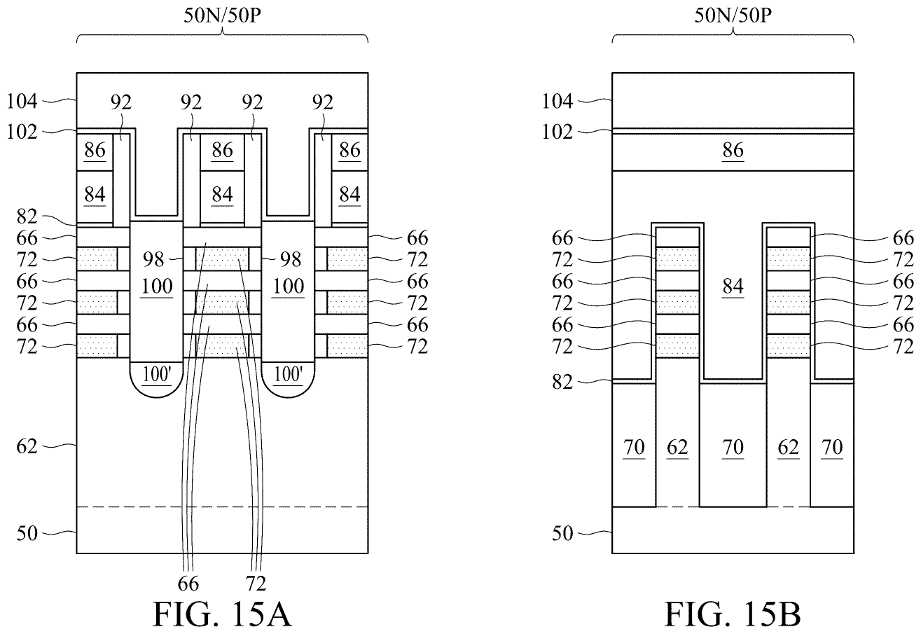

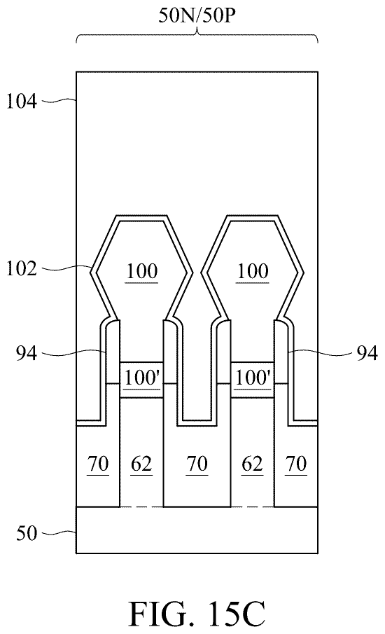

In FIGS. 15A-15C, a first ILD 104 is deposited over the epitaxial source/drain regions 100, the fin spacers 94, the gate spacers 92, the masks 86 (if present), and/or the dummy gates 84. The first ILD 104 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some cases, the first ILD 104 may extend below top surfaces of the STI regions 70 and/or below bottom surfaces of the epitaxial source/drain regions 100.

In some embodiments, a contact etch stop layer (CESL) 102 is formed between the first ILD 104 and the epitaxial source/drain regions 100, the fin spacers 94, the gate spacers 92, the masks 86 (if present), and/or the dummy gates 84. The CESL 102 may be formed of a dielectric material having a high etching selectivity from the etching of the first ILD 104, such as silicon nitride, silicon oxide, silicon oxynitride, a combination thereof, or the like, which may be formed using any suitable deposition process, such as CVD, ALD, or the like.

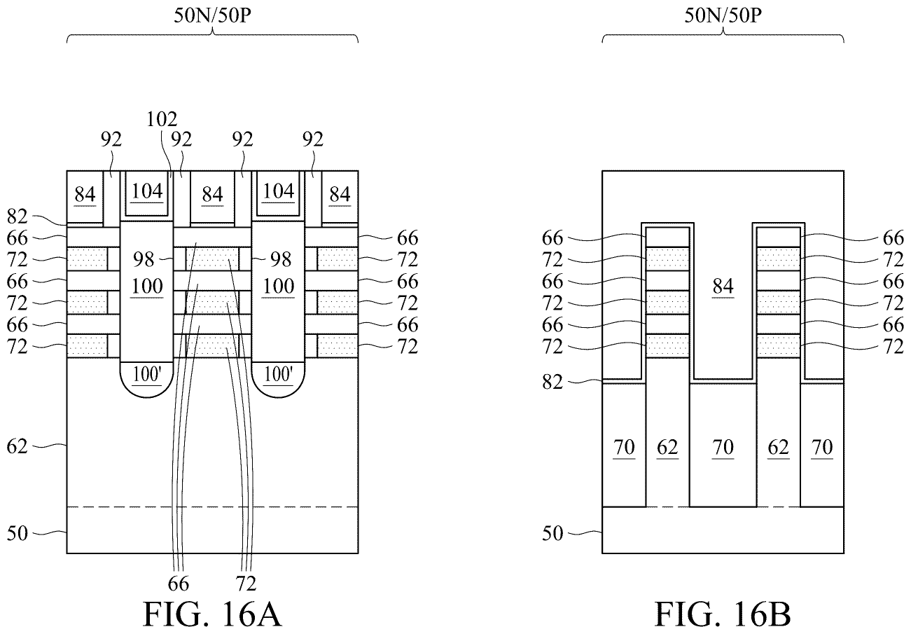

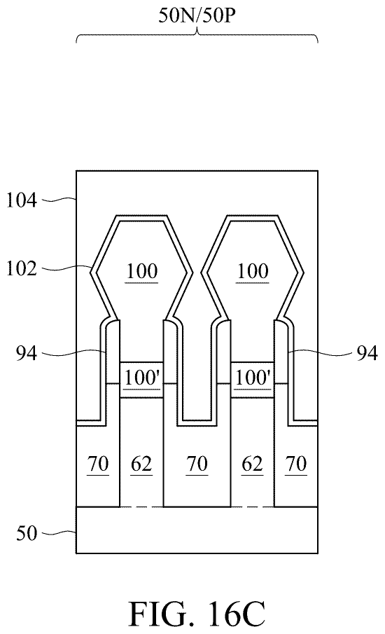

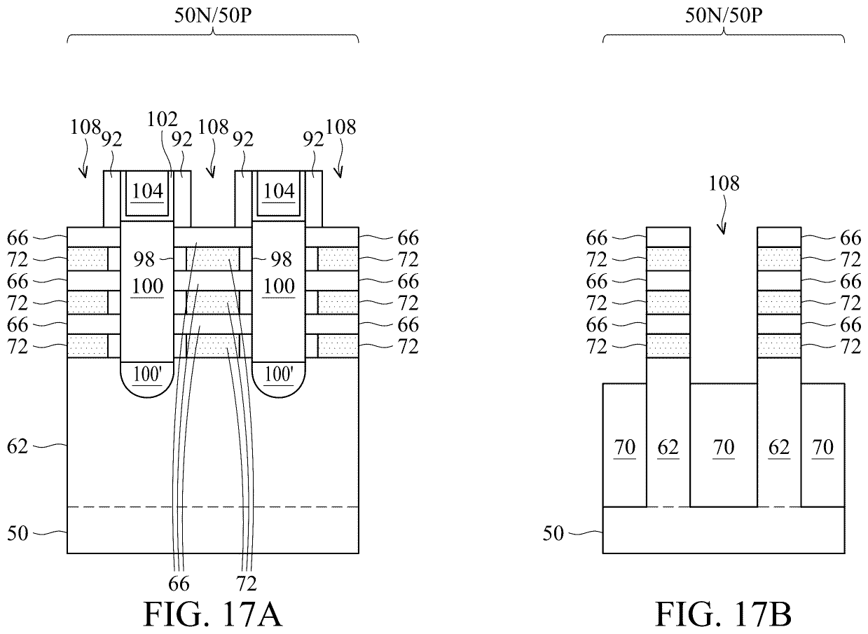

In FIGS. 16A-16C, a removal process is performed to level the top surfaces of the first ILD 104 with the top surfaces of the gate spacers 92 and the dummy gates 84, in accordance with some embodiments. In some embodiments, the planarization process removes the masks 86 and portions of the gate spacers 92 along sidewalls of the masks 86. The removal process may include a planarization process such as a chemical mechanical polish (CMP), a grinding process, an etch-back process, a combination thereof, or the like. After the planarization process, top surfaces of the first ILD 104, the gate spacers 92, and the dummy gates 84 may be substantially level or coplanar (within process variations). Accordingly, the top surfaces of the dummy gates 84 may be exposed through the first ILD 104. In other embodiments, the planarization process does not remove the masks 86. In such embodiments, after the planarization process, top surfaces of the first ILD 104, the gate spacers 92, and the masks 86 may be substantially level or coplanar (within process variations).

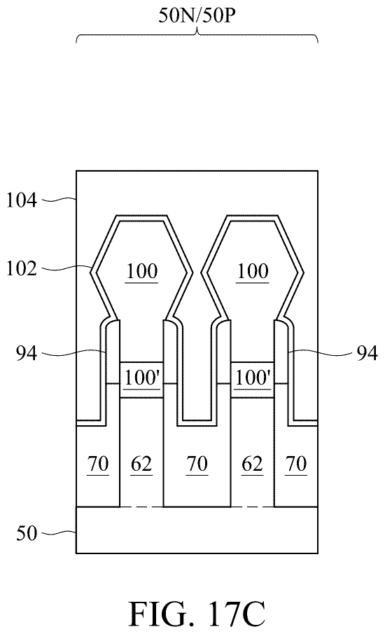

In FIGS. 17A-17C, the masks 86 (if present) and the dummy gates 84 are removed in one or more etching steps, such that recesses 108 are formed between the gate spacers 92. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 104 and the gate spacers 92. During the removal, the dummy dielectrics 82 may be used as etch stop layers when the dummy gates 84 are etched. The dummy dielectrics 82 may then be removed after the removal of the dummy gates 84.

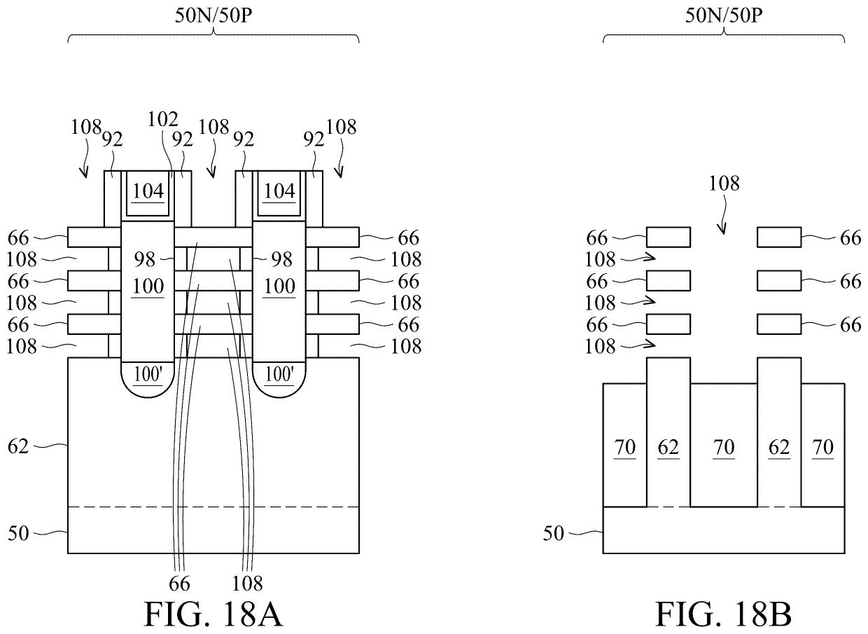

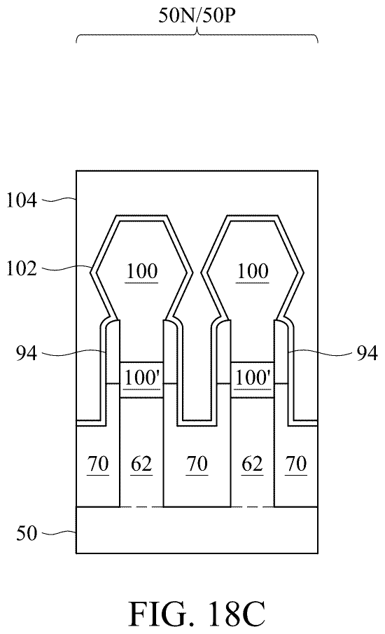

In FIGS. 18A-18C, the dummy regions 72 are removed, extending the recesses 108, in accordance with some embodiments. Removing the dummy regions 72 may include performing an isotropic etching process such as wet etching or the like. The etching process may use etchants which are selective to the materials of the dummy regions 72, while the nanostructures 66 remain relatively unetched as compared to the dummy regions 72. In some embodiments, the STI regions 70 may be at least partially etched while removing the dummy regions 72, but the total amount of loss in the STI regions 70 may be reduced by controlling etching parameters (e.g., timing) while removing the dummy regions 72. In other embodiments, the STI regions 70 may be protected from etching by a hard mask, such as the hard mask described previously for FIG. 5.

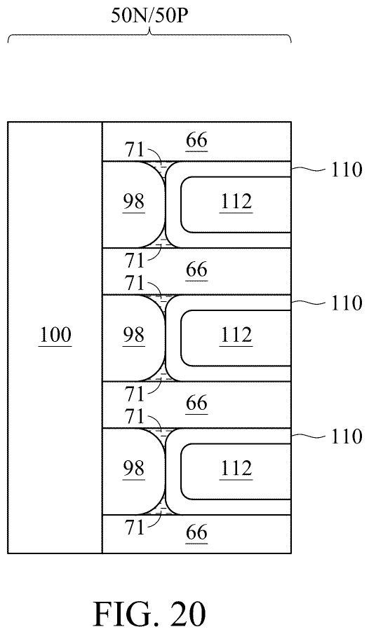

The dummy material 71 of the dummy regions 72 may be completely removed, or a residue of the dummy material 71 may remain on some sidewall portions of the inner spacers 98 in the recesses 108 (see e.g., FIG. 20). After removing the dummy regions 72, each recess 108 exposes portions of nanostructures 66, which act as channel regions in subsequently completed nanostructure-FETs. Portions of the nanostructures 66 which act as the channel regions are disposed between neighboring pairs of the epitaxial source/drain regions 100.

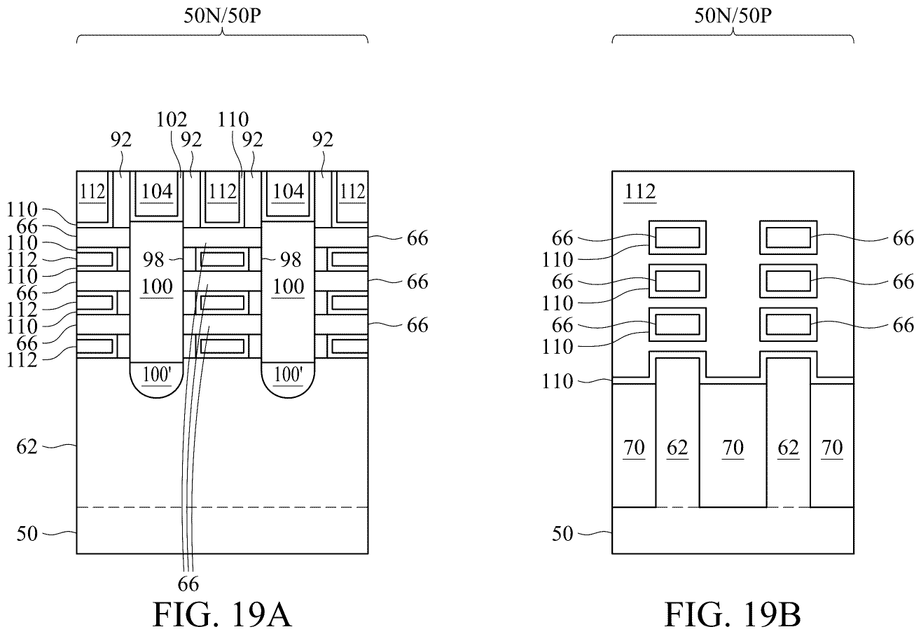

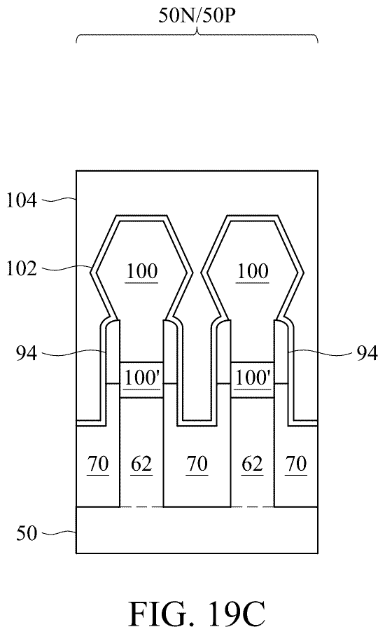

In FIGS. 19A-19C, gate dielectric layers 110 and gate electrodes 112 are formed for replacement gate structures, in accordance with some embodiments. The gate dielectric layers 110 are deposited conformally in the recesses 108. The gate dielectric layers 110 may be formed on top surfaces and sidewalls of the substrate 50 and on exposed top surfaces, sidewalls, and bottom surfaces of the nanostructures 66. The gate dielectric layers 110 may also be deposited on top surfaces of the first ILD 104, the CESL 102, the gate spacers 92, and/or the STI regions 70.

In accordance with some embodiments, the gate dielectric layers 110 comprise one or more dielectric layers, such as layer(s) of oxide, metal oxide, the like, or combinations thereof. For example, in some embodiments, the gate dielectric layers 110 may comprise a silicon oxide layer and a metal oxide layer over the silicon oxide layer. In some embodiments, the gate dielectric layers 110 include a high-k dielectric material, and in these embodiments, the gate dielectric layers 110 may have a k value greater than about 7.0, and may include a metal oxide or a silicate of hafnium, aluminum, zirconium, lanthanum, manganese, barium, titanium, lead, and combinations thereof. The structure of the gate dielectric layers 110 may be the same or different in the n-type region 50N and the p-type region 50P. The formation methods of the gate dielectric layers 110 may include molecular-beam deposition (MBD), ALD, PECVD, and the like.

The gate electrodes 112 are deposited over the gate dielectric layers 110, respectively, and fill the remaining portions of the recesses 108. The gate electrodes 112 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 112 are illustrated in FIGS. 19A and 19B, the gate electrodes 112 may comprise any number of liner layers, any number of work function tuning layers, and a fill material. Any combination of the layers which make up the gate electrodes 112 may be deposited over surfaces of the nanostructures 66.

The formation of the gate dielectric layers 110 in the n-type region 50N and the p-type region 50P may occur simultaneously such that the gate dielectric layers 110 in each region are formed from the same materials, and the formation of the gate electrodes 112 may occur simultaneously such that the gate electrodes 112 in each region are formed from the same materials. In some embodiments, the gate dielectric layers 110 in each region may be formed by distinct processes, such that the gate dielectric layers 110 may be different materials and/or have a different number of layers, and/or the gate electrodes 112 in each region may be formed by distinct processes, such that the gate electrodes 112 may be different materials and/or have a different number of layers. Various masking steps may be used to mask and expose appropriate regions when using distinct processes.

After the filling of the recesses 108, a planarization process, such as a CMP, may be performed to remove the excess portions of the gate dielectric layers 110 and the material of the gate electrodes 112, which excess portions are over the top surface of the first ILD 104. The remaining portions of material of the gate electrodes 112 and the gate dielectric layers 110 thus form replacement gate structures of the resulting nanostructure-FETs. The gate electrodes 112 and the gate dielectric layers 110 may be collectively referred to as gate structures or gate stacks.

FIG. 20 illustrates a detailed view of various elements of FIG. 19A, including the epitaxial source/drain regions 100, the gate dielectric layers 110, the gate electrodes 112, the nanostructures 66, and the inner spacers 98. The view of FIG. 20 may be a magnified view of a portion of a nanostructure-FET in the n-type region 50N or the p-type region 50P. In some embodiments, illustrated by FIG. 20, a residue of the dummy material 71 may remain on the inner spacers 98, such as between the inner spacers 98 and the gate dielectric layers 110. For example, the dummy regions 72 may not be fully removed, and the gate dielectric layers 110 may be formed on the remaining dummy material 71 of the dummy regions 72. Because the dummy material 71 is an insulating material (e.g., silicon oxide or the like), the remaining residue may not significantly impact the electrical performance of the resulting device.

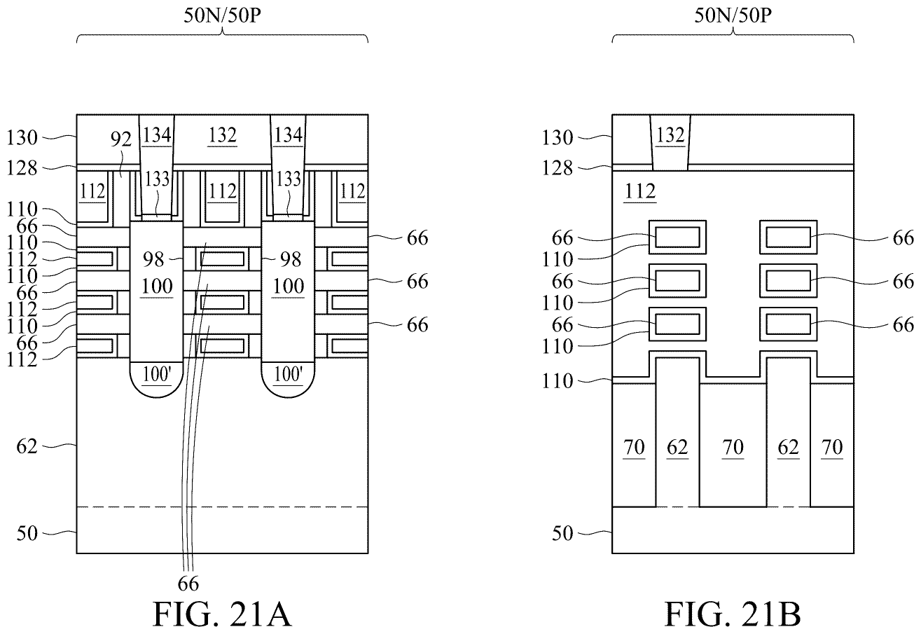

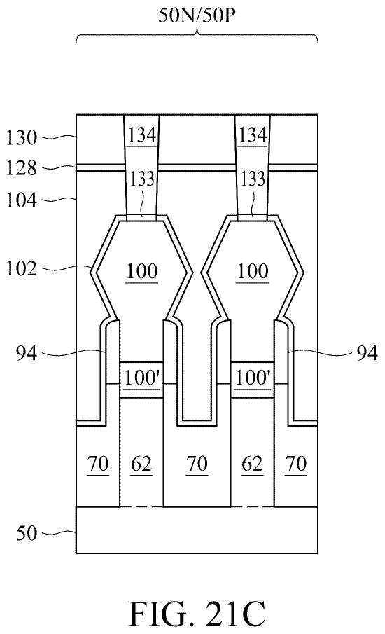

In FIGS. 21A-21C, a second ILD 130 is deposited over the gate spacers 92, the CESL 102, the first ILD 104, and the gate structures, in accordance with some embodiments. In some embodiments, the second ILD 130 is a flowable film formed by a flowable CVD method. In some embodiments, the second ILD 130 is formed of a dielectric material such as PSG, BSG, BPSG, USG, or the like, which may be formed by any suitable deposition process, such as CVD, PECVD, or the like.

In some embodiments, an etch stop layer (ESL) 128 is formed before deposition of the second ILD 130. The ESL 128 may be formed of a dielectric material having a high etching selectivity from the etching of the second ILD 130, such as silicon nitride, silicon oxide, silicon oxynitride, or the like, which may be formed by any suitable deposition process, such as CVD, ALD, or the like.

In other embodiments, the gate structures (including the gate dielectric layers 110 and the corresponding overlying gate electrodes 112) are recessed, so that recesses (not separately illustrated) are formed directly over the gate structures between opposing portions of gate spacers 92. A gate mask (not separately illustrated) comprising one or more layers of dielectric material, such as silicon nitride, silicon oxynitride, or the like, may be filled in the recesses, followed by a planarization process to remove excess portions of the dielectric material. Subsequently formed gate contacts (such as the gate contacts 132, discussed below) penetrate through the gate mask to contact the top surfaces of the recessed gate electrodes 112.

Further in FIGS. 21A-21C, gate contacts 132 and source/drain contacts 134 are formed to contact, respectively, the gate electrodes 112 and the epitaxial source/drain regions 100. The gate contacts 132 may be physically and electrically coupled to the gate electrodes 112. The source/drain contacts 134 may be physically and electrically coupled to the epitaxial source/drain regions 100.

As an example of forming the gate contacts 132 and the source/drain contacts 134, openings for the gate contacts 132 are formed through the second ILD 130 and the ESL 128, and openings for the source/drain contacts 134 are formed through the second ILD 130, the ESL 128, the first ILD 104, and the CESL 102. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 130. The remaining liner and conductive material form the gate contacts 132 and the source/drain contacts 134 in the openings. The gate contacts 132 and the source/drain contacts 134 may be formed in distinct processes, or may be formed in the same process. Although shown as being formed in the same cross-sections, it should be appreciated that each of the gate contacts 132 and the source/drain contacts 134 may be formed in different cross-sections, which may avoid shorting of the contacts.

Optionally, metal-semiconductor alloy regions 133 are formed at the interfaces between the epitaxial source/drain regions 100 and the source/drain contacts 134. The metal-semiconductor alloy regions 133 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 133 can be formed before the material(s) of the source/drain contacts 134 by depositing a metal in the openings for the source/drain contacts 134 and then performing a thermal annealing process. The metal can be any metal capable of reacting with the semiconductor materials (e.g., silicon, silicon carbide, silicon germanium, germanium, etc.) of the epitaxial source/drain regions 100 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 134, such as from surfaces of the metal-semiconductor alloy regions 133. The material(s) of the source/drain contacts 134 can then be formed on the metal-semiconductor alloy regions 133.

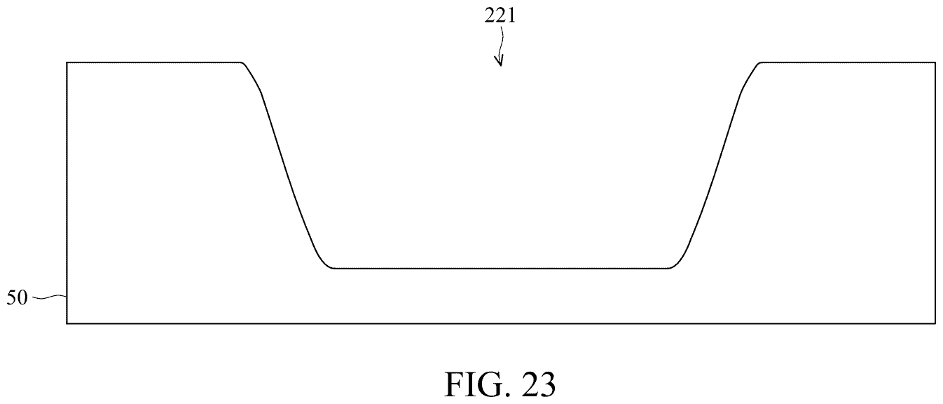

In some embodiments, techniques described in FIGS. 2-21C for forming nanostructure-FETs may also be used to form mark structures on a device, die, or wafer. The mark structures may include, for example, frame marks, alignment marks, lithography alignment marks, overlay marks, metrology structures, identification marks, test structures, or the like. FIGS. 23-61 illustrate the formation of example mark structures 220, 230, 240, and 250, in accordance with some embodiments. The mark structures of FIGS. 23-61 are intended as illustrative examples, and other mark structures are possible. Many of the materials and techniques of FIGS. 23-61 are similar to those described previously for FIGS. 2-21C, and accordingly some details are not repeated. In some embodiments, the process steps for forming the mark structures may be concurrent with the similar process steps for forming nanostructure-FETs.

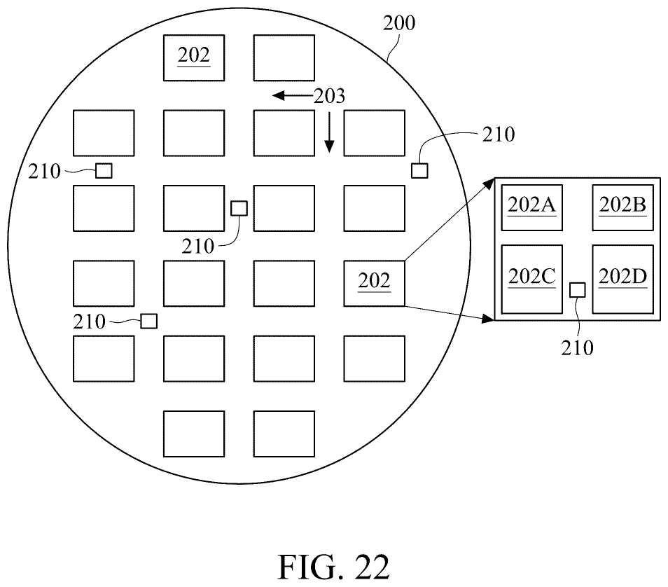

FIG. 22 illustrates a plan view (e.g., a top view) of a wafer 200, in accordance with some embodiments. The wafer 200 may include a plurality of chip regions 202 (e.g., “die regions,” “package regions,” “active regions,” or the like) separated from each other by dicing regions 203. In some embodiments, each of the chip regions 202 may include a semiconductor device. Such semiconductor devices may include a transistor such as nanostructure-FETs, FinFETs, other multi-gate transistors, planar transistors, bipolar junction transistors, or other types of devices such as resistors, capacitors, inductors, diodes, fuses, static random-access memory (SRAM), and/or other logic circuits, etc. For example, the semiconductor devices may comprise nanostructure-FETs formed using techniques similar to those described previously for FIGS. 1-21C. The dicing regions 203 may also be referred to scribe regions, singulation regions, isolation regions, or the like. In some embodiments, the wafer 200 may be singulated along the dicing regions 203 to separate the chip regions 202 from each other and form individual chips. In some embodiments, the wafer 200 further includes mark structures 210 disposed in the dicing regions 203. The mark structures 210 may be similar to the mark structures 220, 230, 240, or 250 described below, for example. In some embodiments, the mark structures 210 may be disposed at an edge of the wafer 200. In other embodiments, the mark structures 210 may be disposed at corners of the chip regions 202. In yet other embodiments, the mark structures 210 may be disposed at edges of the chip regions 202. In some embodiments, when the mark structures 210 are formed in the dicing regions 203, the mark structures 210 may be damaged or destroyed by the singulation process.

In some embodiments, each of the chip regions 202 includes one or more chips. For example, in the embodiments illustrated in FIG. 22, each of the chip regions 202 includes four chips, such as chips 202A, 202B, 202C, and 202D. In other embodiments, each of the chip regions 202 may include more than four chips or fewer than four chips, depending on the design requirements. In some embodiments, when each of the chip regions 202 includes a plurality of chips, the mark structures 210 may be disposed within the chip regions 202 between adjacent chips. In such embodiments, the mark structures 210 are not damaged or destroyed during the singulation process and may be present in the final product.

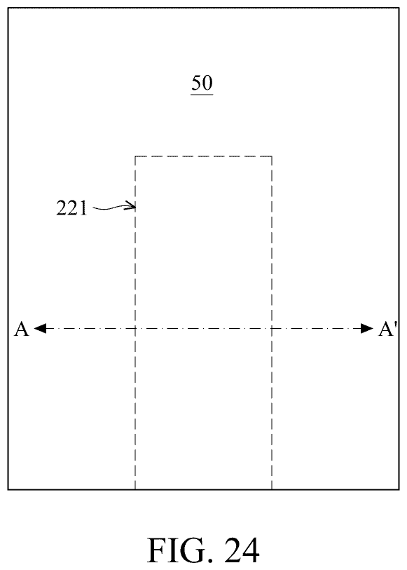

FIGS. 23-34 show various views of intermediate steps in the formation of a mark structure 220, in accordance with some embodiments. In some cases, the mark structure 220 may be considered a “zero layer mark” or the like. In FIGS. 23 and 24, a trench 221 is formed in the substrate 50, in accordance with some embodiments. FIG. 23 illustrates a cross-sectional view and FIG. 24 illustrates a plan view. The cross-sectional view of FIG. 23 may be along a cross-section similar to the cross-section A-A′ shown in FIG. 24, which itself may be similar to the reference cross-section A-A′ of FIG. 1 in some cases. Some details and features are not shown in the plan view of FIG. 24, for clarity. The trench 221 may be formed using suitable photolithography and etching techniques. The trench 221 may have sloped sidewalls, as shown in FIG. 23, or may have vertical sidewalls.

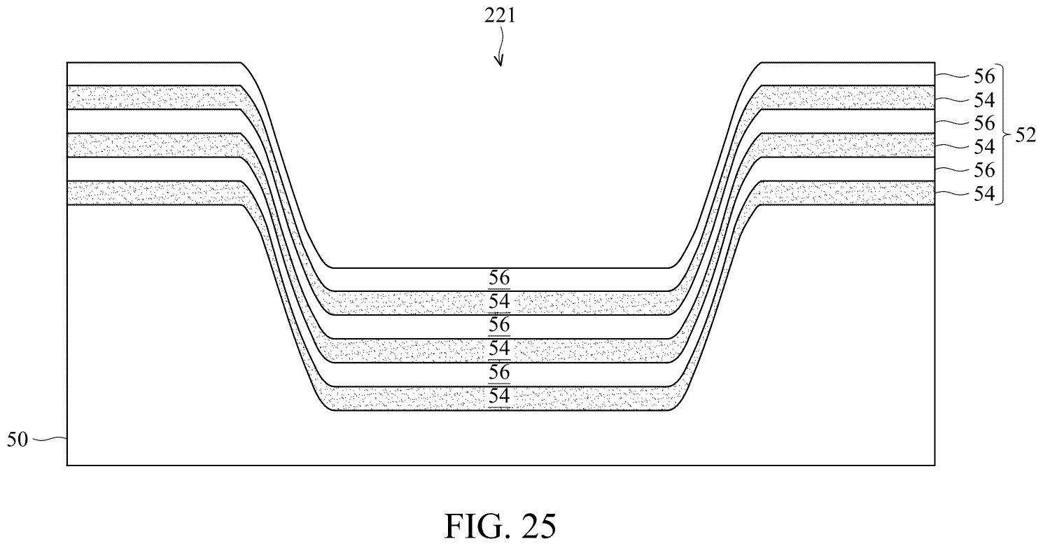

In FIG. 25, a multi-layer stack 52 is formed over the substrate 50 and within the trench 221, in accordance with some embodiments. The multi-layer stack 52 may be similar to the multi-layer stack 52 described previously for FIG. 2. For example, the multi-layer stack 52 includes alternating first semiconductor layers 54 and second semiconductor layers 56, which may be similar to those described previously in FIG. 2. For example, in some embodiments, the first semiconductor layers 54 are silicon germanium and the second semiconductor layers 56 are silicon, though other materials are possible. More or fewer semiconductor layers 54/56 may be formed in other embodiments.

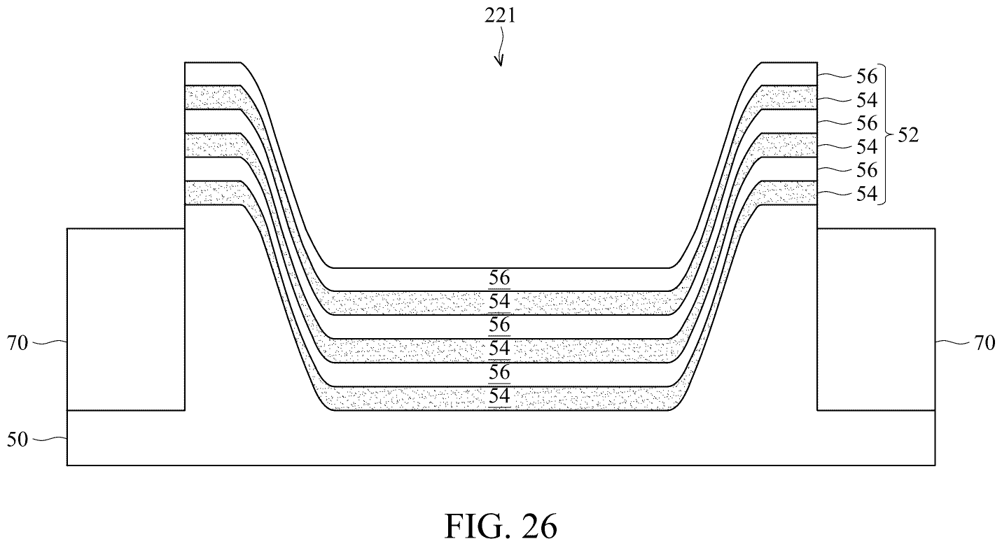

In FIG. 26, the structure is etched and STI regions 70 are formed, in accordance with some embodiments. The structure may be etched using techniques similar to those described for FIG. 3. For example, a mask (not illustrated) may be formed over the multi-layer stack 52 in and around the trench 221, and then an etching process may be performed to recess regions not covered by the mask. The mask may then be removed. A width of the mask may be greater than a width of the trench 221. The STI regions 70 may then be formed in the recessed regions using techniques similar to those described for FIGS. 4 and 5. For example, an insulation material may be deposited and then recessed to form the STI regions 70. A hard mask (not illustrated) may be formed over the STI regions 70 in some embodiments, which may be similar to the hard mask described previously for FIG. 5.

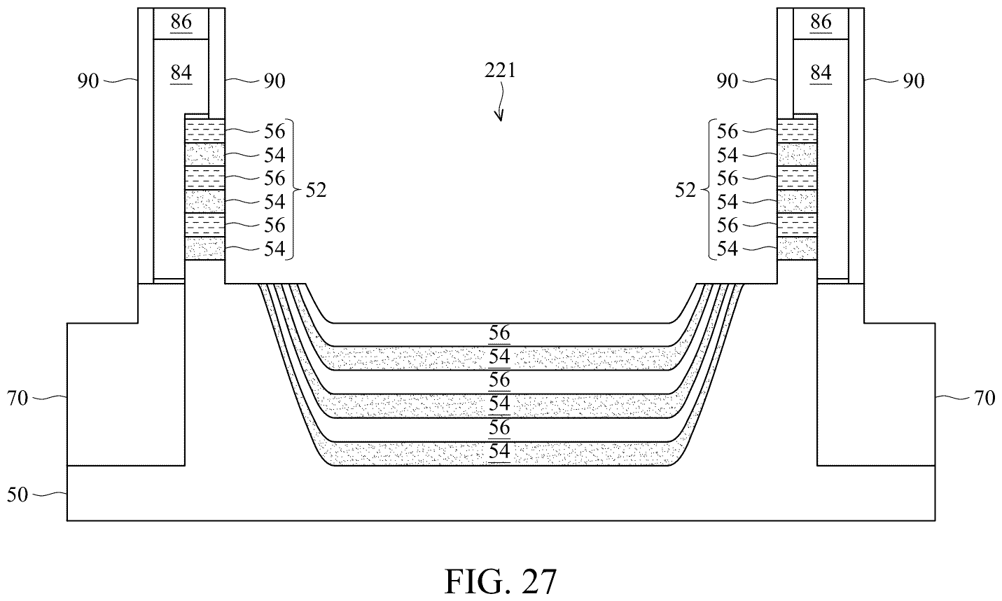

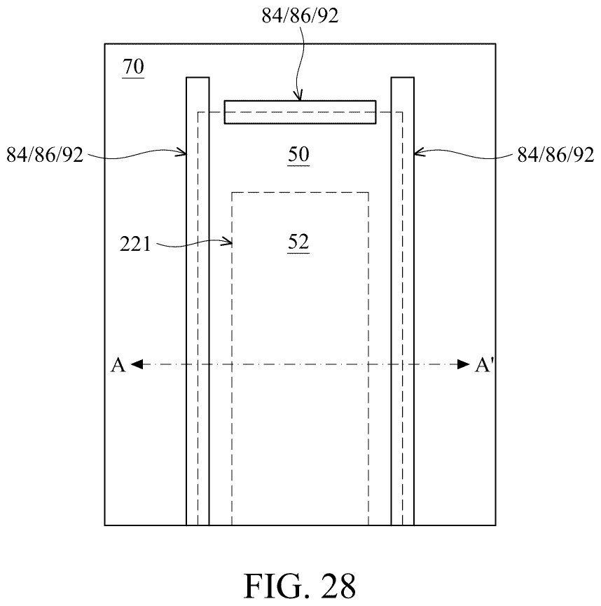

In FIGS. 27 and 28, dummy dielectrics 82, dummy gates 84, masks 86, are formed over the structure, in accordance with some embodiments. FIG. 27 illustrates a cross-sectional view and FIG. 28 illustrates a plan view. The dummy dielectrics 82, dummy gates 84, and masks 86 may be formed using techniques similar to those described previously for FIGS. 6A-6B. As shown in FIGS. 27-28, the dummy dielectrics 82, dummy gates 84 and/or masks 86 may extend partially over the multi-layer stack 52 and partially over the STI regions 70. A spacer layer 90 may then be deposited over the structure and etched, similar to the formation of gate spacers 92 described for FIGS. 7A-8C.

As shown in FIG. 27, portions of the multi-layer stack 52 remain beneath the dummy dielectrics 82, dummy gates 84, masks 86, and/or spacer layer 90. In some cases, the portions of the first semiconductor layers 54 and the second semiconductor layers 56 beneath the dummy dielectrics 82, dummy gates 84, masks 86, and/or spacer layer 90 may be considered nanostructures, which may be similar to the nanostructures 64/66 of the nanostructure-FETs. Other portions of the multi-layer stack 52 may remain in the trench 221, for example at the bottom of the trench 221 as shown in FIG. 27.

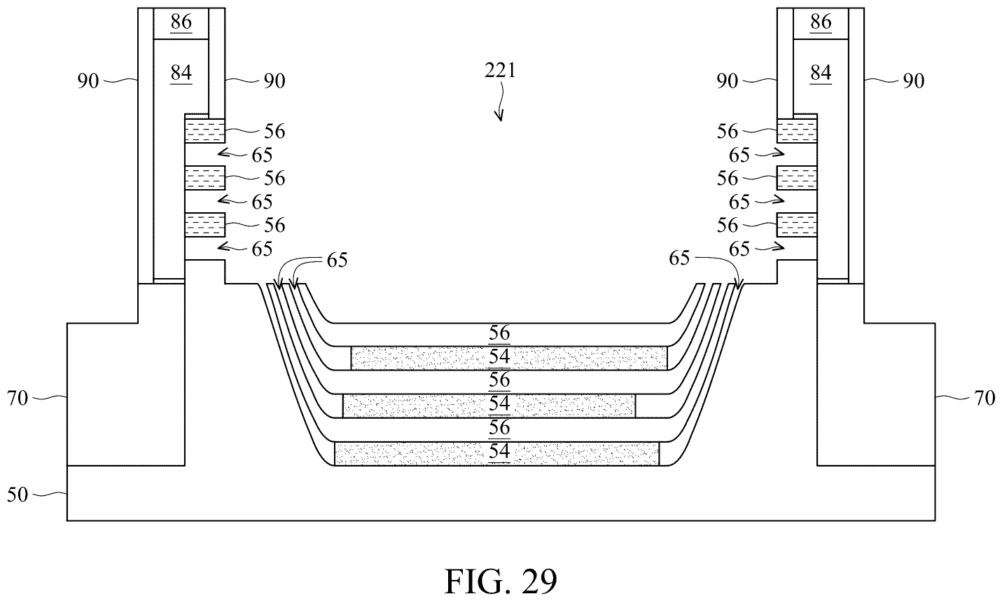

In FIG. 29, the first semiconductor layers 54 are etched to form openings 65, in accordance with some embodiments. The first semiconductor layers 54 may be etched using an etching process similar to (or the same as) the etching process described previously for FIGS. 9A-9B. For example, the etching process may include any acceptable etching process that selectively etches the material of the first semiconductor layers 54 at a faster rate than the material of the second semiconductor layers 56. The first semiconductor layers 54 beneath the dummy dielectrics 82, dummy gates 84, masks 86, and/or spacer layer 90 may be partially or completely removed, in some cases.

In some embodiments, the material of the first semiconductor layers 54 in the trench 221 is only partially removed by the etching process, such that material of the first semiconductor layers 54 remains in the trench 221 after the etching process is complete. The openings 65 formed by the etching process may not extend fully across the trench 221, and may only extend partially into the trench 221. Accordingly, the etching process may recess the first semiconductor layers 54 in the trench 221, and the remaining portions of the first semiconductor layers 54 in the trench 221 may have an opening 65 at one or more sides. The remaining portions of the first semiconductor layers in the trench 221 may have similar widths or different widths.

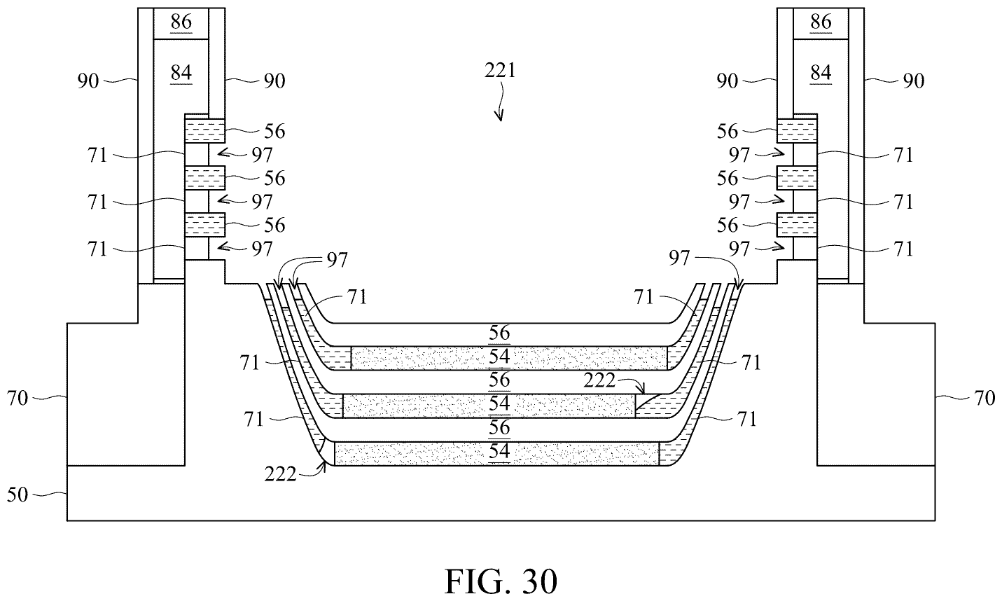

In FIG. 30, a dummy material 71 is deposited in the openings 65, in accordance with some embodiments. The dummy material 71 may be similar to the dummy material 71 described for FIGS. 10A-10B, and may be deposited using similar techniques. For example, the dummy material 71 may be an oxide material or the like. After depositing the dummy material 71, an etching process is performed to remove portions of the dummy material 71 and form recesses 97. The etching process may be similar to the etching process used to form the dummy regions 72 and the sidewall recesses 97 as described for FIGS. 11A-11B. The dummy material 71 may thus be recessed from adjacent surfaces of the substrate 50 and/or second semiconductor layers 56 both in and out of the trench 221.

As shown in FIG. 30, the dummy material 71 may be deposited in openings 65 in the trench 221. The dummy material 71 may be deposited on one or more sides of the remaining first semiconductor layers 54. For example, a remaining first semiconductor layer 54 may be sandwiched between regions of dummy material 71. In some cases, the dummy material 71 physically contacts or covers sidewalls of remaining first semiconductor layers 54. In some cases, the dummy material 71 only partially fills an opening 65 such that a gap 222 (e.g., a void or the like) is formed between a sidewall of a remaining first semiconductor layer 54 and an adjacent region of dummy material 71. A gap 222 may fully separate a first semiconductor layer 54 from the adjacent dummy material 71 or may partially separate a first semiconductor layer 54 from the adjacent dummy material 71. Two example gaps 222 are shown in FIG. 30, but any number of gaps 222, including zero, may be formed.

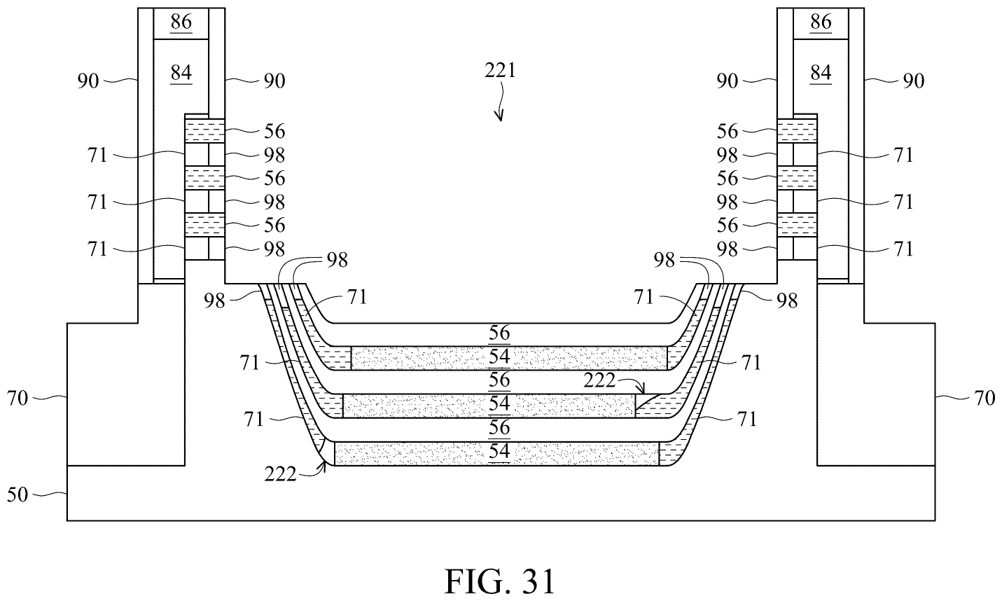

In FIG. 31, inner spacers 98 are formed in the recesses 97, in accordance with some embodiments. The inner spacers 98 may be formed using materials and techniques similar to those described previously for FIGS. 12A-12B. For example, in some embodiments, the inner spacers 98 are formed by conformally depositing an insulating material in the sidewall recesses 97 and subsequently etching the insulating material. Although outer sidewalls of inner spacers 98 are illustrated as being flush (e.g. approximately coplanar) with adjacent surfaces of the substrate 50 and/or second semiconductor layers 56, the outer sidewalls of the inner spacers 98 may extend beyond or be recessed from adjacent surfaces of the substrate 50 and/or second semiconductor layers 56. As shown in FIG. 31, a region of dummy material 71 in the trench 221 may be sandwiched between an inner spacer 98 and a first semiconductor layer 54, or between an inner spacer 98 and a gap 222, in some cases.

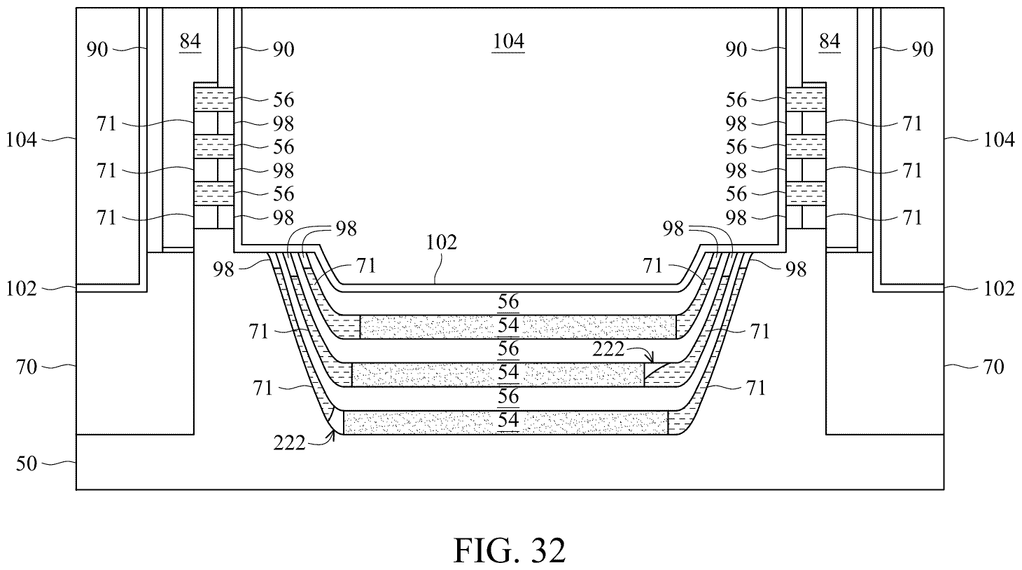

In FIG. 32, a first ILD 104 is deposited over the structure and in the trench 221, in accordance with some embodiments. The first ILD 104 may be similar to the first ILD 104 described for FIGS. 15A-15C, and may be formed using similar techniques. In some embodiments, a contact etch stop layer (CESL) 102 may be deposited before depositing the first ILD 104, which may be similar to the CESL 102 described for FIGS. 15A-15C. A planarization process may be performed that removes excess material of the first ILD 104 and removes the masks 86, in some embodiments. The planarization process may be similar to that described for FIGS. 16A-16C, and may be, for example a CMP process or the like. After performing the planarization process, top surfaces of the first ILD 104, the CESL 102, the spacer layer 90, and the dummy gates 84 may be approximately level or coplanar. As shown in FIG. 32, the first ILD 104 may completely fill the trench 221, in some embodiments.

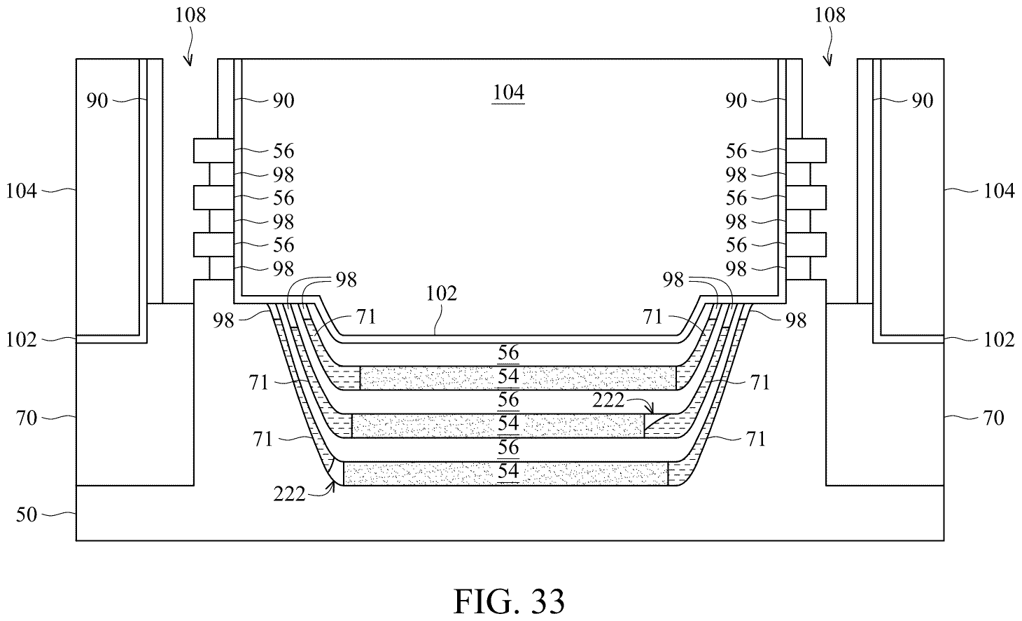

In FIG. 33, dummy gates 84 and exposed dummy material 71 are removed to form recesses 108, in accordance with some embodiments. The dummy gates 84 may be removed using one or more etching processes similar to those described previously for FIGS. 17A-17C. The dummy dielectrics 82 may also be removed. An etching process may then be performed to remove the exposed dummy material 71, which may be similar to the etching process described for FIGS. 18A-18C to remove the dummy regions 72. As shown in FIG. 33, the dummy material 71 formed in the trench 221 is not exposed and thus is not etched when the other dummy material 71 is removed.

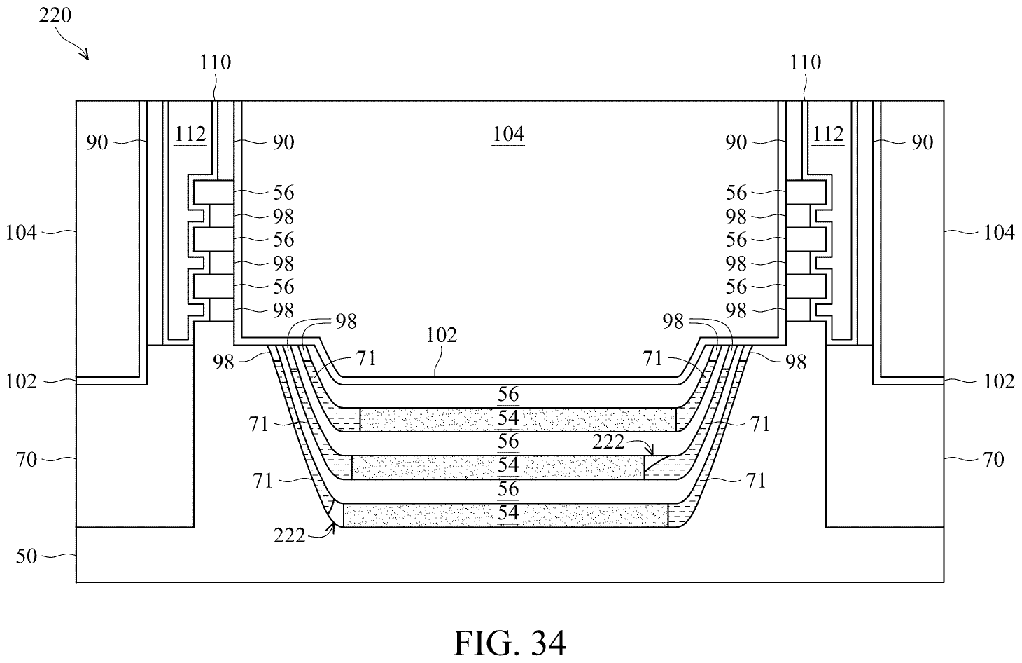

In FIG. 34, gate structure layers are formed in the recesses 108, in accordance with some embodiments. The gate structure layers may comprise, for example, gate dielectric layers 110 and gate electrodes 112, which may be similar to those described previously for FIGS. 19A-19C. Other gate structure layers, such as liner layers, work function tuning layers, or the like, may also be deposited. After the filling of the recesses 108, a planarization process, such as a CMP process, may be performed to remove the excess portions of the gate dielectric layers 110 and the material of the gate electrodes 112. Additional layer deposition or other processing may or may not be subsequently performed on the mark structure 220. The first semiconductor layers 54 and the dummy material 71 remain in the final mark structure 220. In some cases, some of the processes described previously for FIGS. 21A-21C may be subsequently performed. Other variations or additional process steps are possible.

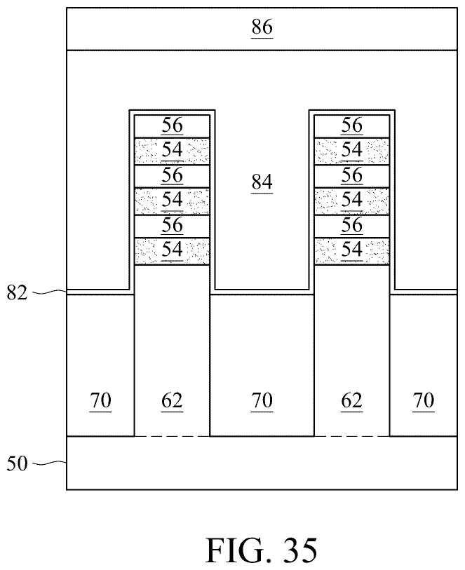

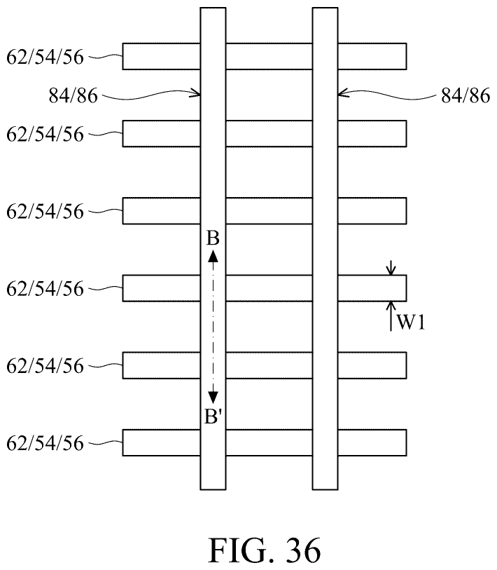

FIGS. 35-41 show various views of intermediate steps in the formation of a mark structure 230, in accordance with some embodiments. FIGS. 35 and 36 illustrate the formation of dummy dielectrics 82, dummy gates 84, and masks 86 over fins 62, in accordance with some embodiments. FIG. 35 illustrates a cross-sectional view and FIG. 36 illustrates a plan view. The cross-sectional view of FIG. 35 may be along a cross-section similar to the cross-section B-B′ shown in FIG. 36, which itself may be similar to the reference cross-section B-B′ of FIG. 1 in some cases. Some details and features are not shown in the plan view of FIG. 36, for clarity. The fins 62 may be similar to the fins 62 described previously for FIGS. 2-5 and may be formed using similar techniques. For example, a multi-layer stack 52 of first semiconductor layers 54 and second semiconductor layers 56 may be formed over a substrate 50 and then patterned, similar to the process described for FIG. 3. In some cases, the remaining portions of first semiconductor layers 54 and second semiconductor layers 56 over the fins 62 may be considered nanostructures, nanosheets, or the like. Accordingly, after patterning, the multi-layer stack 52 may be considered a nanostructure stack, a nanosheet stack or the like. In some embodiments, the fins 62 of the mark structure 230 have a width W1 that is greater than about 90 nm, though other widths W1 are possible. STI regions 70 may be formed around the fins 62, similar the STI regions 70 described for FIGS. 4-5. Dummy dielectrics 82, dummy gates 84, and masks 86 may then be formed over the fins 62 and STI regions 70, similar to FIGS. 6A-6B.

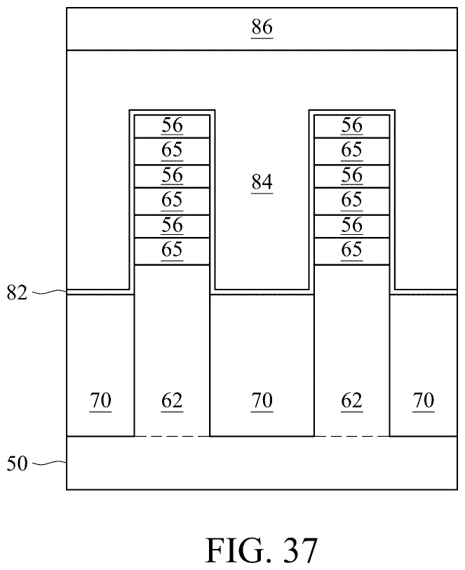

In FIG. 37, the first semiconductor layers 54 are etched to form openings 65, in accordance with some embodiments. The first semiconductor layers 54 may be etched using an etching process similar to (or the same as) the etching process described previously for FIGS. 9A-9B. For example, the etching process may include any acceptable etching process that selectively etches the material of the first semiconductor layers 54 at a faster rate than the material of the second semiconductor layers 56.

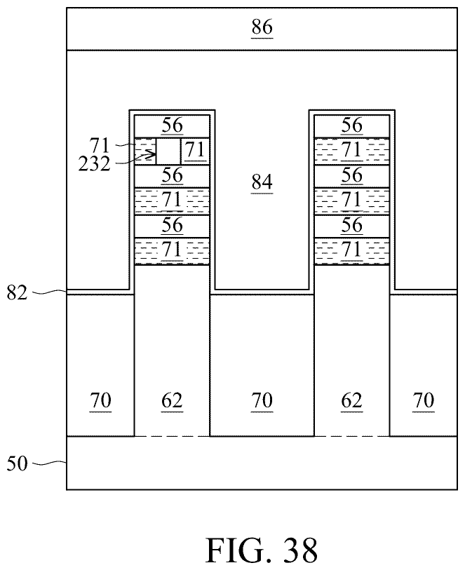

In FIG. 38, a dummy material 71 is deposited in the openings 65, in accordance with some embodiments. The dummy material 71 may be similar to the dummy material 71 described for FIGS. 10A-10B, and may be deposited using similar techniques. For example, the dummy material 71 may be an oxide material or the like. After depositing the dummy material 71, an etching process is performed to remove portions of the dummy material 71 and form recesses 97 (not visible in the cross-section of FIG. 38). The etching process may be similar to the etching process used to form the dummy regions 72 and the sidewall recesses 97 as described for FIGS. 11A-11B. In some cases, the dummy material 71 may form regions similar to the dummy regions 72 described previously. In some cases, the dummy material 71 may not completely fill an opening 65 such that a gap 232 (e.g., a void) is formed within the opening 65. An example gap 232 is shown in FIG. 38. A gap 232 may be within a single region of dummy material 71 or may separate two regions of dummy material 71. Any number of gaps 232 (including zero) may be formed in the various openings 65.

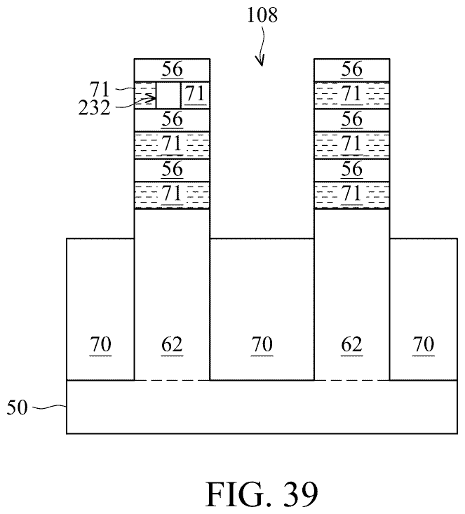

In FIG. 39, the dummy dielectrics 82, dummy gates 84 and masks 86 are removed to form recesses 108, in accordance with some embodiments. In some embodiments, the masks 86 may be removed by a planarization process, such as that described for FIGS. 16A-16C. The dummy dielectrics 82 and dummy gates 84 may be removed using one or more etching processes similar to those described previously for FIGS. 17A-17C. As shown in FIG. 39, removing the dummy gates 84 exposes sidewalls of the dummy material 71.

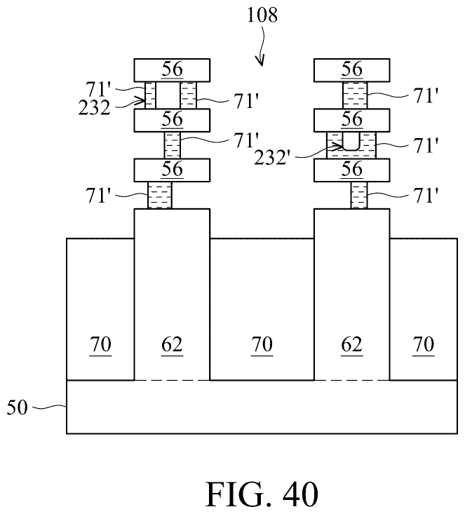

In FIG. 40, an etching process is performed to remove portions of the dummy material 71, in accordance with some embodiments. The etching process may be similar to the etching process described for FIGS. 18A-18C to remove the dummy regions 72. As shown in FIG. 40, in some embodiments, the dummy material 71 is not completely removed by the etching process, with portions of dummy material 71 remaining above, below, or between the second semiconductor layers 56. The remaining portions of dummy material 71 are referred to herein as dummy portions 71′. One or more than one dummy portions 71′ may be formed by etching a region of dummy material 71. In some cases, a gap 232′ may be formed in a dummy portion 71′ or between two adjacent dummy portions 71′, an example of which is shown in FIG. 40. The dummy portions 71′ may have similar widths or different widths, and may be laterally aligned or laterally offset. In some cases, the dummy material 71 above, below, or between second semiconductor layers 56 may be completely removed (not illustrated) such that no dummy portion 71′ is formed. In some cases, forming fins 62 having widths W1 of about 90 nm or greater may increase the chance that the dummy material 71 is not completely removed and dummy portions 71′ are formed.

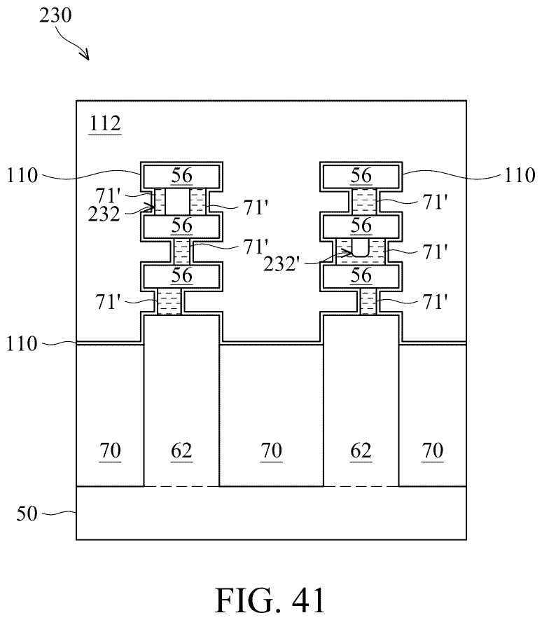

In FIG. 41, gate structure layers are formed in the recesses 108, in accordance with some embodiments. The gate structure layers may be deposited over surfaces of the second semiconductor layers 56 and over surfaces of the dummy portions 71′. The gate structure layers may comprise, for example, gate dielectric layers 110 and gate electrodes 112, which may be similar to those described previously for FIGS. 19A-19C. Other gate structure layers, such as liner layers, work function tuning layers, or the like, may also be deposited. After the filling of the recesses 108, a planarization process, such as a CMP process, may be performed to remove the excess portions of the gate dielectric layers 110 and the material of the gate electrodes 112. Additional layer deposition or other processing may or may not be subsequently performed on the mark structure 230. The dummy portions 71′ remain in the final mark structure 230. In some cases, some of the processes described previously for FIGS. 21A-21C may be subsequently performed. Other variations or additional process steps are possible.

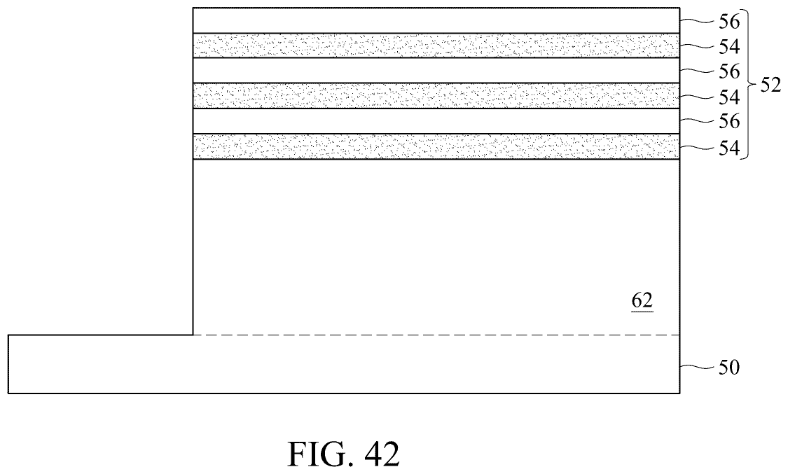

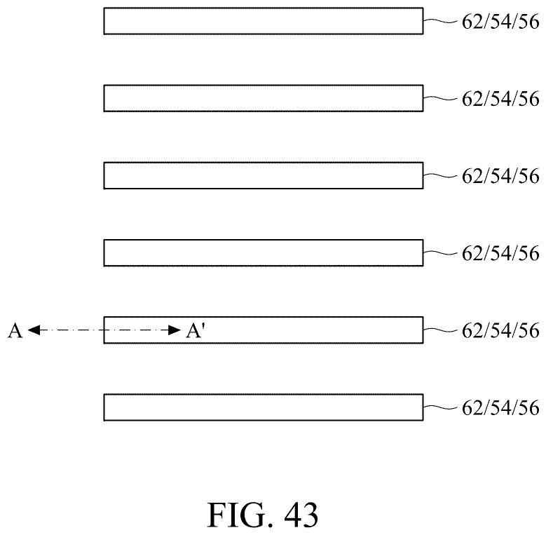

FIGS. 42-51 show various views of intermediate steps in the formation of a mark structure 240, in accordance with some embodiments. In FIG. 42, a multi-layer stack 52 is formed over a substrate 50 and patterned, in accordance with some embodiments. FIG. 42 illustrates a cross-sectional view and FIG. 43 illustrates a plan view. The cross-sectional view of FIG. 42 may be along a cross-section similar to the cross-section A-A′ shown in FIG. 43, which itself may be similar to the reference cross-section A-A′ of FIG. 1 in some cases. Some details and features are not shown in the plan view of FIG. 43, for clarity. The multi-layer stack 52 may be similar to the multi-layer stack 52 described previously for FIG. 2. For example, the multi-layer stack 52 includes alternating first semiconductor layers 54 and second semiconductor layers 56, which may be similar to those described previously in FIG. 2. More or fewer semiconductor layers 54/56 may be formed in other embodiments. The multi-layer stack 52 and the substrate 50 may then be patterned, forming fins 62 in the substrate 50. The patterning process may be similar to the process described for FIG. 3. In some cases, the remaining portions of first semiconductor layers 54 and second semiconductor layers 56 over the fins 62 may be considered nanostructures, nanosheets, or the like. Accordingly, after patterning, the multi-layer stack 52 may be considered a nanostructure stack, a nanosheet stack or the like.

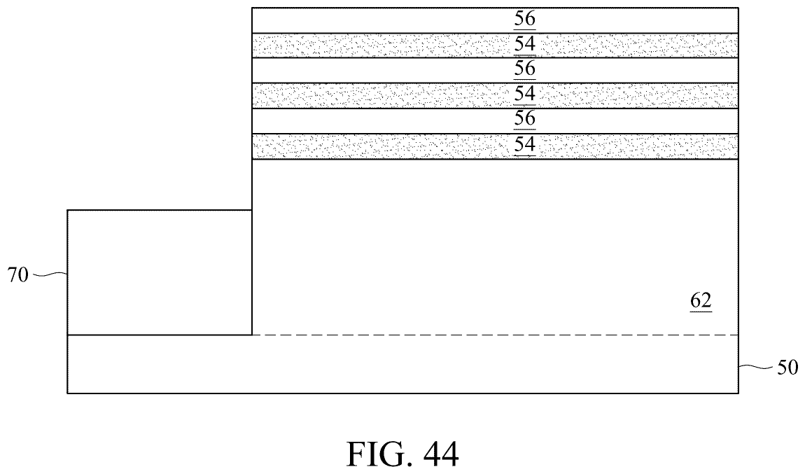

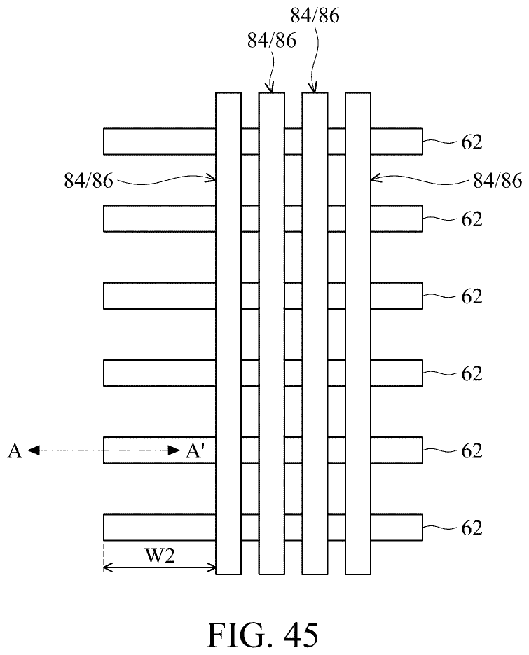

In FIGS. 44 and 45, STI regions 70, dummy dielectrics 82, dummy gates 84, and masks 86 may be formed, in accordance with some embodiments. FIG. 44 illustrates a cross-sectional view and FIG. 45 illustrates a plan view. The STI regions 70 may be formed around the fins 62, similar the STI regions 70 described for FIGS. 4-5. The STI regions 70 may be formed using techniques similar to those described for FIGS. 4 and 5. For example, an insulation material may be deposited and then recessed to form the STI regions 70. A hard mask (not illustrated) may be formed over the STI regions 70 in some embodiments, which may be similar to the hard mask described previously for FIG. 5. The dummy dielectrics 82, dummy gates 84, and masks 86 may then be formed over the fins 62 and STI regions 70. The dummy dielectrics 82, dummy gates 84, and masks 86 may be formed using techniques similar to those described previously for FIGS. 6A-6B. The dummy dielectrics 82, dummy gates 84, and masks 86 are not illustrated in the cross-section of FIG. 44. In some embodiments, a distance W2 between an end of a fin 62 and a dummy gate 84 may be greater than about 100 nm, though other distances W2 are possible.

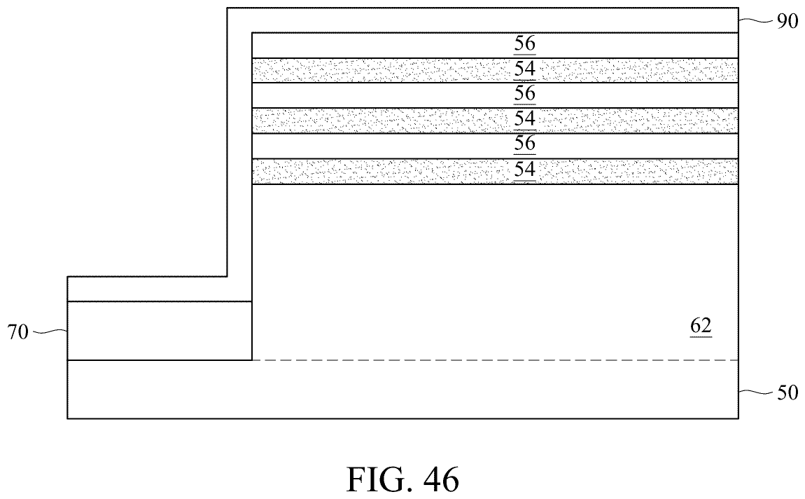

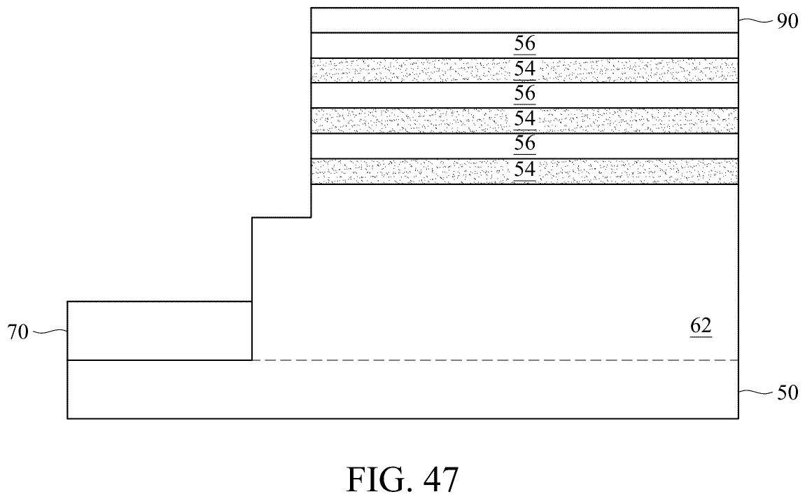

In FIG. 46, a spacer layer 90 is deposited over the structure, in accordance with some embodiments. The spacer layer 90 may be similar to the spacer layer 90 described for FIGS. 7A-7B, and may be formed using similar techniques. In FIG. 47, the spacer layer 90, the semiconductor layers 54/56, the fins 62, and/or the STI regions 70 are etched, in accordance with some embodiments. The etching may be an etching process similar to that used to form the source/drain recesses 96 as described previously for FIGS. 8A-8C. The etching may remove sidewall portions of the spacer layer 90 such that sidewalls of the semiconductor layers 54/56 are exposed.

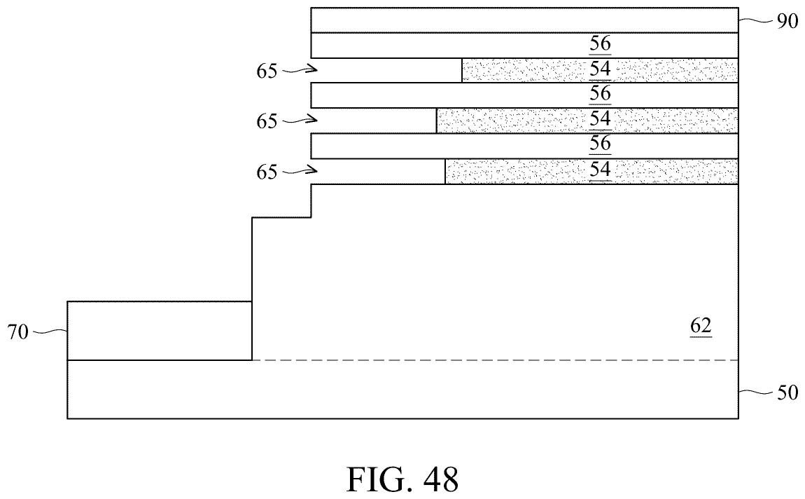

In FIG. 48, the first semiconductor layers 54 are etched to form openings 65, in accordance with some embodiments. The first semiconductor layers 54 may be etched using an etching process similar to (or the same as) the etching process described previously for FIGS. 9A-9B. For example, the etching process may include any acceptable etching process that selectively etches the material of the first semiconductor layers 54 at a faster rate than the material of the second semiconductor layers 56. As shown in FIG. 48, the etching process may only partially remove the first semiconductor layers 54 such that portions of the first semiconductor layers 54 remain. In other words, the etching process recesses sidewalls of the first semiconductor layers 54. In some cases, having a distance W2 that is greater than about 100 nm can reduce the chance that the first semiconductor layers 54 are completely removed by the etching process. The sidewalls of the remaining portions of the first semiconductor layers 54 may be laterally aligned or may be laterally offset.

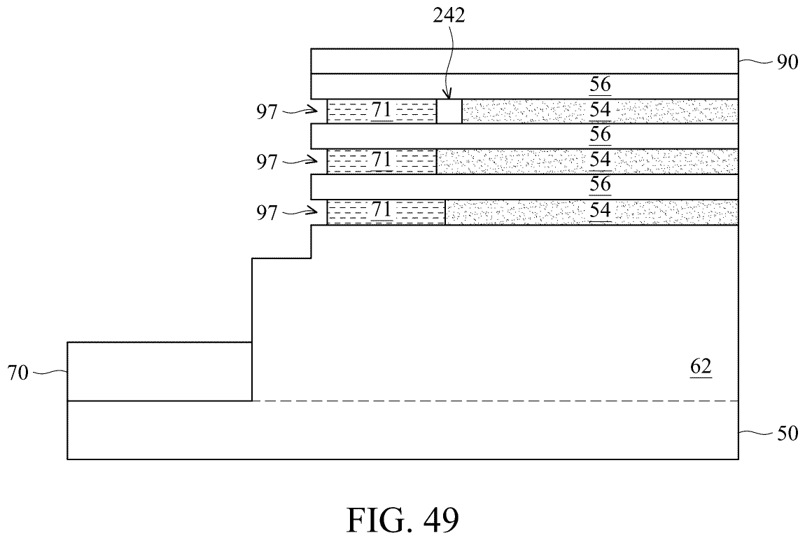

In FIG. 49, a dummy material 71 is deposited in the openings 65, in accordance with some embodiments. The dummy material 71 may be similar to the dummy material 71 described for FIGS. 10A-10B, and may be deposited using similar techniques. For example, the dummy material 71 may be an oxide material or the like. After depositing the dummy material 71, an etching process is performed to remove portions of the dummy material 71 and form recesses 97. The etching process may be similar to the etching process used to form the dummy regions 72 and the sidewall recesses 97 as described for FIGS. 11A-11B. In some cases, the dummy material 71 may form regions similar to the dummy regions 72 described previously. The dummy material 71 may be formed on the sidewalls of the first semiconductor layers 54. In some cases, a region of dummy material 71 may only partially extend into an opening 65. In such cases, a gap 242 (e.g., a void) is formed between the dummy material 71 and the first semiconductor layer 54. An example gap 242 is shown in FIG. 49. A gap 242 may fully or partially separate a region of dummy material 71 from a first semiconductor layer 54. Any number of gaps 242 (including zero) may be formed in the various openings 65.

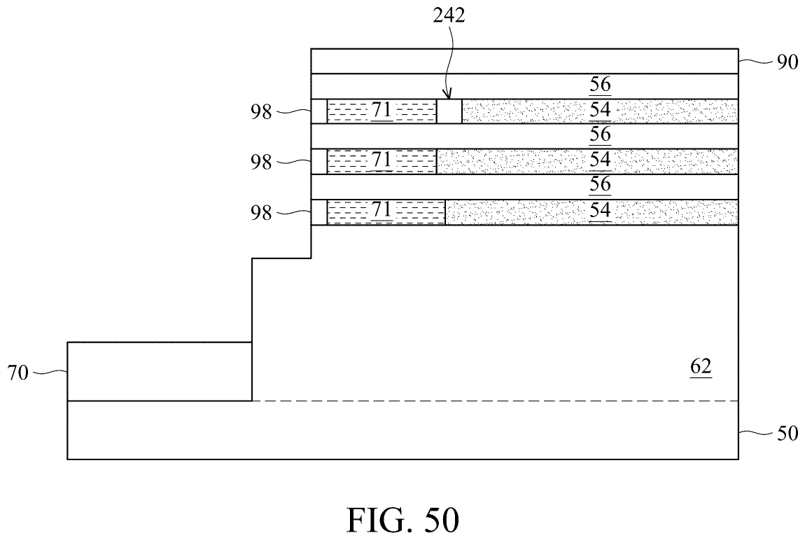

In FIG. 50, inner spacers 98 are formed in the recesses 97, in accordance with some embodiments. The inner spacers 98 may be formed using materials and techniques similar to those described previously for FIGS. 12A-12B. For example, in some embodiments, the inner spacers 98 are formed by conformally depositing an insulating material in the sidewall recesses 97 and subsequently etching the insulating material. Although outer sidewalls of inner spacers 98 are illustrated as being flush (e.g. approximately coplanar) with adjacent surfaces of the substrate 50 and/or second semiconductor layers 56, the outer sidewalls of the inner spacers 98 may extend beyond or be recessed from adjacent surfaces of the substrate 50 and/or second semiconductor layers 56. As shown in FIG. 50, a region of dummy material 71 may be sandwiched between an inner spacer 98 and a first semiconductor layer 54, or between an inner spacer 98 and a gap 242, in some cases.

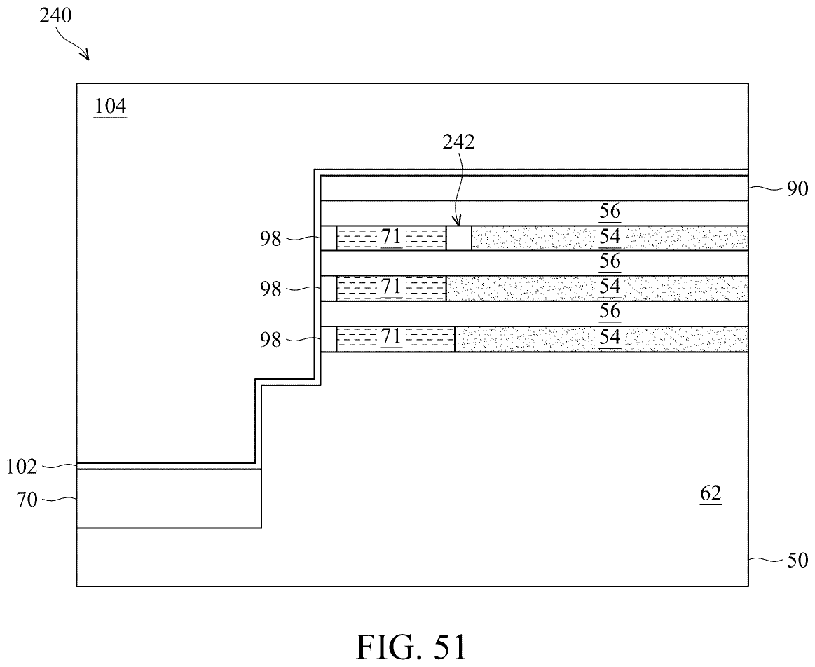

In FIG. 51, a first ILD 104 is deposited over the structure, in accordance with some embodiments. The first ILD 104 may be similar to the first ILD 104 described for FIGS. 15A-15C, and may be formed using similar techniques. In some embodiments, a contact etch stop layer (CESL) 102 may be deposited before depositing the first ILD 104, which may be similar to the CESL 102 described for FIGS. 15A-15C. Additional layer deposition or other processing may or may not be subsequently performed on the mark structure 240. Because the dummy material 71 of the mark structure 240 is fully surrounded, the dummy material 71 in the mark structure 240 is protected from etching processes that remove dummy material 71, such as those described previously for FIGS. 18A-18C. In this manner, the first semiconductor layers 54 and the dummy material 71 remain in the final mark structure 240. In some cases, some of the processes described previously for FIGS. 19A-21C may be subsequently performed. Other variations or additional process steps are possible.

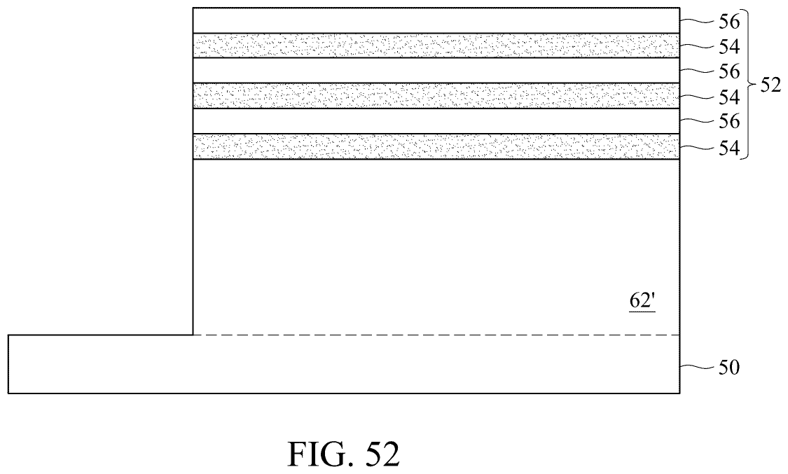

FIGS. 52-61 show various views of intermediate steps in the formation of a mark structure 250, in accordance with some embodiments. In FIG. 52, a multi-layer stack 52 is formed over a substrate 50 and patterned, in accordance with some embodiments. The multi-layer stack 52 may be similar to the multi-layer stack 52 described previously for FIG. 2. For example, the multi-layer stack 52 includes alternating first semiconductor layers 54 and second semiconductor layers 56, which may be similar to those described previously in FIG. 2. More or fewer semiconductor layers 54/56 may be formed in other embodiments. The multi-layer stack 52 and the substrate 50 may then be patterned, forming a fin-like region 62′ in the substrate 50. The patterning process may be similar to the process described for FIG. 3. In some cases, the remaining portions of first semiconductor layers 54 and second semiconductor layers 56 over the fin-like region 62′ may be considered nanostructures, nanosheets, or the like. Accordingly, after patterning, the multi-layer stack 52 may be considered a nanosheet stack or the like.

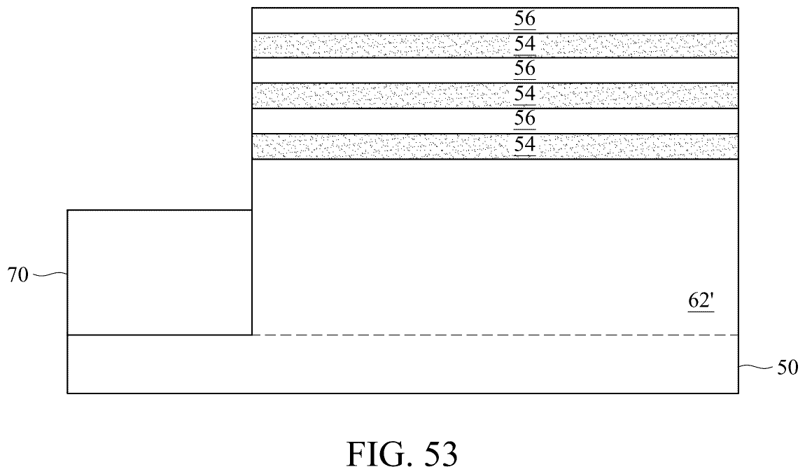

In FIG. 53, an STI region 70 is formed around the fin-like region 62′, in accordance with some embodiments. The STI region 70 may be similar the STI regions 70 described for FIGS. 4-5, and may be formed using similar techniques. For example, an insulation material may be deposited and then recessed to form the STI region 70. A hard mask (not illustrated) may be formed over the STI region 70 in some embodiments, which may be similar to the hard mask described previously for FIG. 5.

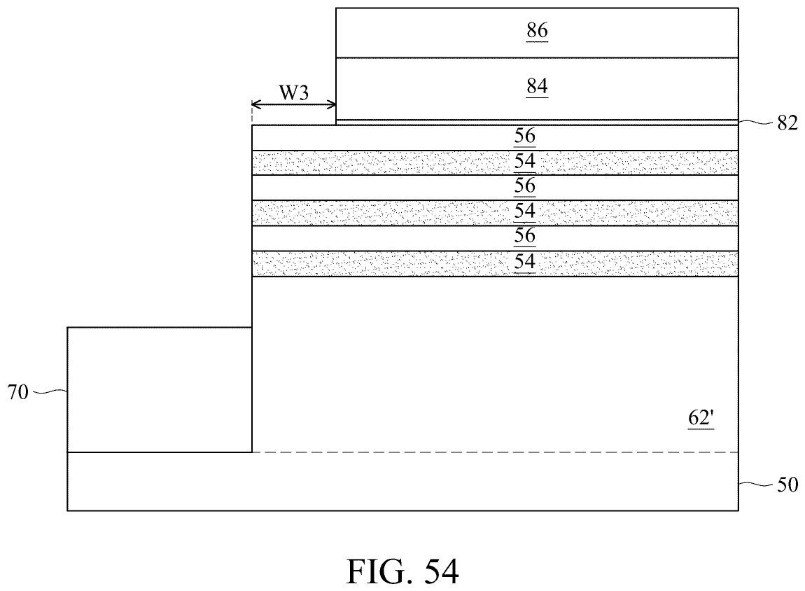

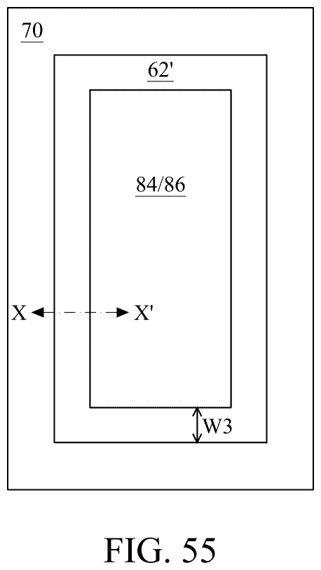

In FIGS. 54 and 55, dummy dielectrics 82, dummy gate 84, and mask 86 are formed over the fin-like region 62′, in accordance with some embodiments. FIG. 54 illustrates a cross-sectional view and FIG. 55 illustrates a plan view. The cross- sectional view of FIG. 54 may be along a cross-section similar to the cross-section X-X′ shown in FIG. 55. Some details and features are not shown in the plan view of FIG. 55, for clarity. The dummy dielectrics 82, dummy gate 84, and mask 86 may be formed using techniques similar to those described previously for FIGS. 6A-6B. As shown in FIG. 55, the dimensions of the fin-like region 62′ may be greater than the dimensions of the overlying dummy gate 84. In some embodiments, a distance W3 between a sidewall of the fin-like region 62′and a sidewall of the overlying dummy gate 84 may be greater than about 100 nm, though other distances W3 are possible.

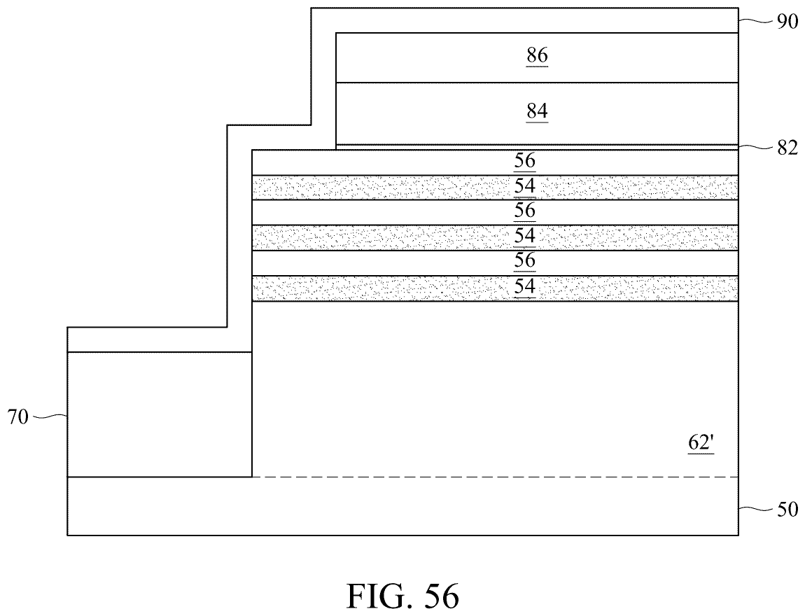

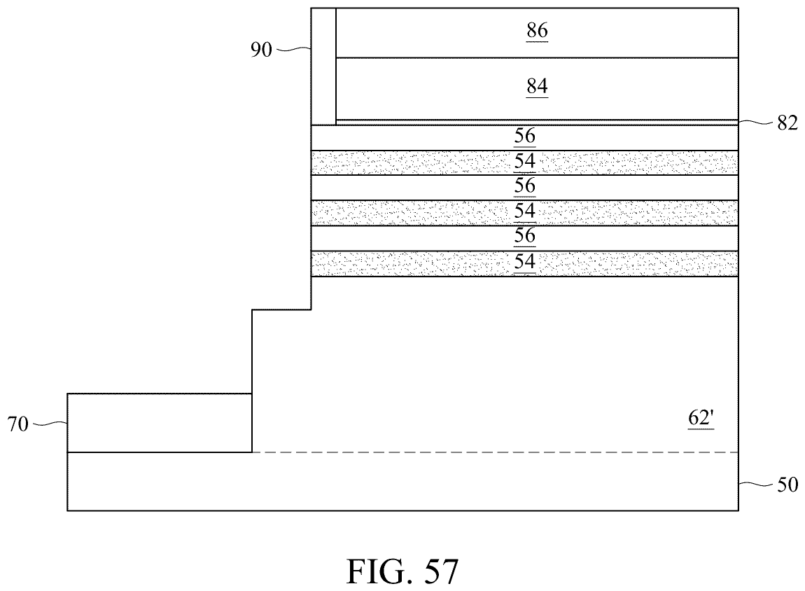

In FIG. 56, a spacer layer 90 is deposited over the structure, in accordance with some embodiments. The spacer layer 90 may be similar to the spacer layer 90 described for FIGS. 7A-7B, and may be formed using similar techniques. In FIG. 57, the spacer layer 90, the semiconductor layers 54/56, the fins 62, and/or the STI regions 70 are etched, in accordance with some embodiments. The etching may be an etching process similar to that used to form the source/drain recesses 96 as described previously for FIGS. 8A-8C. The etching may remove sidewall portions of the spacer layer 90 such that sidewalls of the semiconductor layers 54/56 are exposed. In this manner, remaining portions of the spacer layer 90 may be similar to gate spacers 92, in some cases.

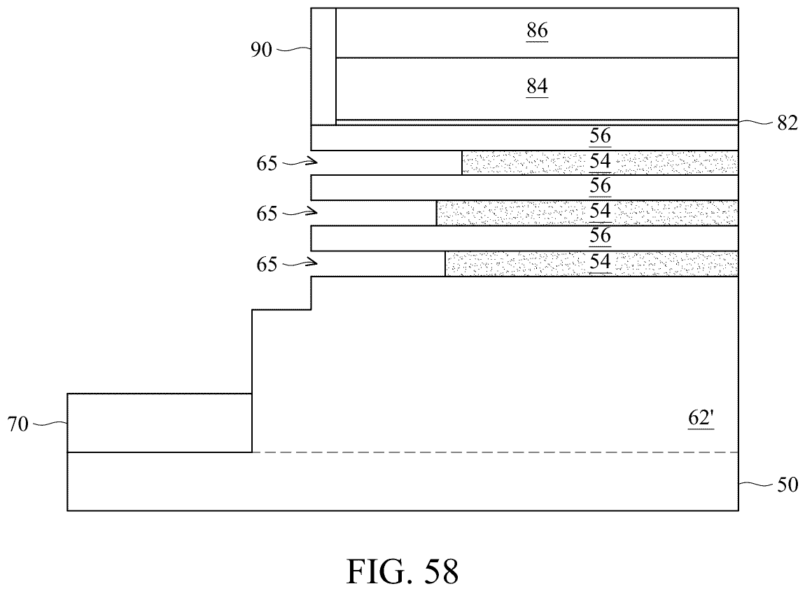

In FIG. 58, the first semiconductor layers 54 are etched to form openings 65, in accordance with some embodiments. The first semiconductor layers 54 may be etched using an etching process similar to (or the same as) the etching process described previously for FIGS. 9A-9B. For example, the etching process may include any acceptable etching process that selectively etches the material of the first semiconductor layers 54 at a faster rate than the material of the second semiconductor layers 56. As shown in FIG. 58, the etching process may only partially remove the first semiconductor layers 54 such that portions of the first semiconductor layers 54 remain. In other words, the etching process recesses sidewalls of the first semiconductor layers 54. In some cases, a dummy gate 84 having a width that is greater than about 200 nm can reduce the risk of second semiconductor layers 56 collapsing after etching of the first semiconductor layers 54. The sidewalls of the remaining portions of the first semiconductor layers 54 may be laterally aligned or may be laterally offset.

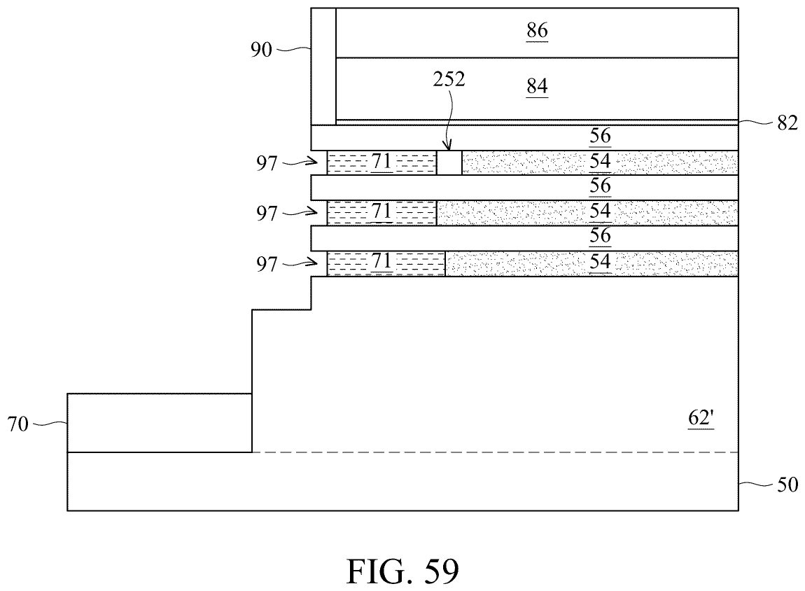

In FIG. 59, a dummy material 71 is deposited in the openings 65, in accordance with some embodiments. The dummy material 71 may be similar to the dummy material 71 described for FIGS. 10A-10B, and may be deposited using similar techniques. For example, the dummy material 71 may be an oxide material or the like. After depositing the dummy material 71, an etching process is performed to remove portions of the dummy material 71 and form recesses 97. The etching process may be similar to the etching process used to form the dummy regions 72 and the sidewall recesses 97 as described for FIGS. 11A-11B. In some cases, the dummy material 71 may form regions similar to the dummy regions 72 described previously. The dummy material 71 may be formed on the sidewalls of the first semiconductor layers 54. In some cases, a region of dummy material 71 may only partially extend into an opening 65. In such cases, a gap 252 (e.g., a void) is formed between the dummy material 71 and the first semiconductor layer 54. An example gap 252 is shown in FIG. 59. A gap 252 may fully or partially separate a region of dummy material 71 from a first semiconductor layer 54. Any number of gaps 252 (including zero) may be formed in the various openings 65.

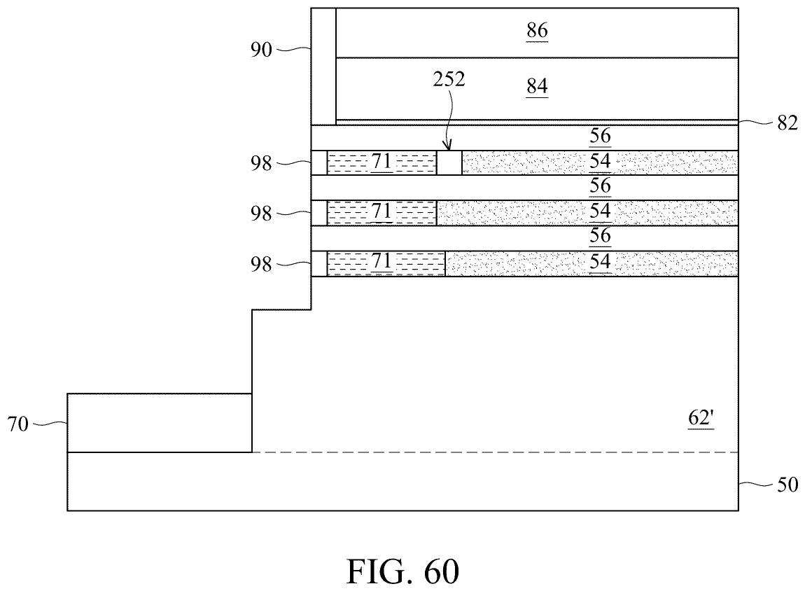

In FIG. 60, inner spacers 98 are formed in the recesses 97, in accordance with some embodiments. The inner spacers 98 may be formed using materials and techniques similar to those described previously for FIGS. 12A-12B. For example, in some embodiments, the inner spacers 98 are formed by conformally depositing an insulating material in the sidewall recesses 97 and subsequently etching the insulating material. Although outer sidewalls of inner spacers 98 are illustrated as being flush (e.g. approximately coplanar) with adjacent surfaces of the substrate 50 and/or second semiconductor layers 56, the outer sidewalls of the inner spacers 98 may extend beyond or be recessed from adjacent surfaces of the substrate 50 and/or second semiconductor layers 56. As shown in FIG. 60, a region of dummy material 71 may be sandwiched between an inner spacer 98 and a first semiconductor layer 54, or between an inner spacer 98 and a gap 252, in some cases.

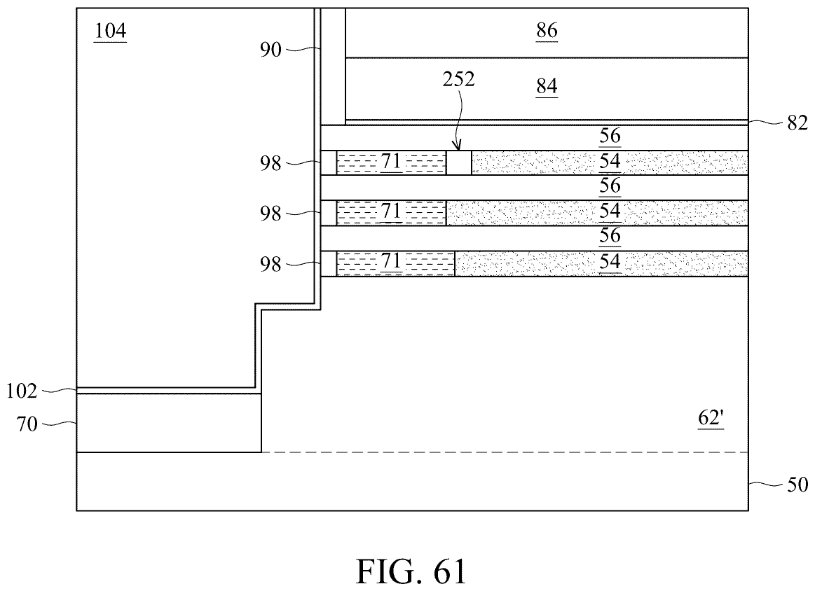

In FIG. 61, a first ILD 104 is deposited over the structure, in accordance with some embodiments. The first ILD 104 may be similar to the first ILD 104 described for FIGS. 15A-15C, and may be formed using similar techniques. In some embodiments, a contact etch stop layer (CESL) 102 may be deposited before depositing the first ILD 104, which may be similar to the CESL 102 described for FIGS. 15A-15C.

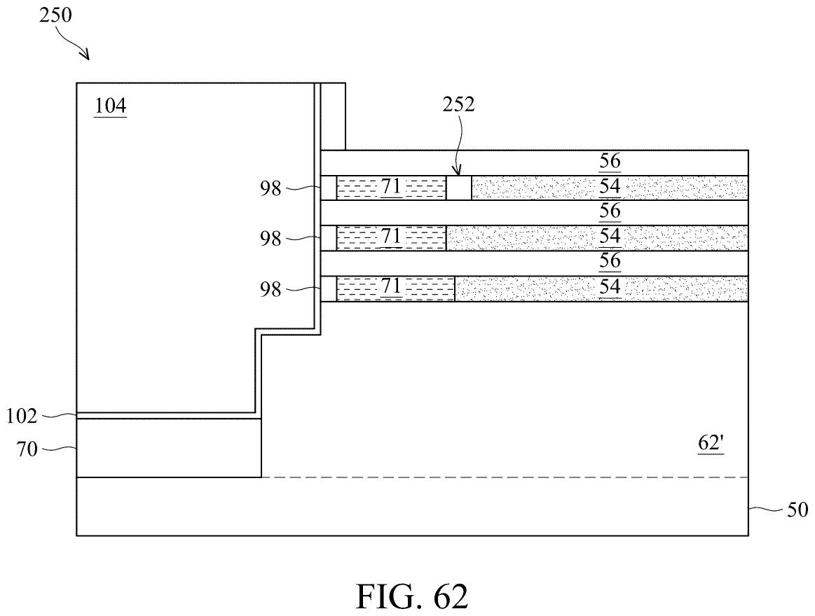

In FIG. 62, the dummy dielectrics 82, dummy gate 84 and mask 86 are removed to form recesses, in accordance with some embodiments. In some embodiments, the masks 86 may be removed by a planarization process, such as that described for FIGS. 16A-16C. The dummy dielectrics 82 and dummy gates 84 may be removed using one or more etching processes similar to those described previously for FIGS. 17A-17C. Additional layer deposition or other processing may or may not be subsequently performed on the mark structure 250. Because the dummy material 71 of the mark structure 250 is fully surrounded, the dummy material 71 in the mark structure 250 is protected from etching processes that remove dummy material 71, such as those described previously for FIGS. 18A-18C. In this manner, the first semiconductor layers 54 and the dummy material 71 remain in the final mark structure 250. In some cases, some of the processes described previously for FIGS. 19A-21C may be subsequently performed. Other variations or additional process steps are possible.

Embodiments may achieve advantages. The techniques described herein allow for the formation of mark structures such as frame marks, alignment marks, or the like using process steps similar to those used to form nanostructure-FETs. In some cases, the mark structures may be formed simultaneously with the nanostructure-FETs. In some embodiments, some semiconductor material of a multi-layer stack is replaced with a dummy dielectric material. For example, nanostructures formed of the semiconductor material can be replaced by dummy regions. This can allow for improved etch selectivity when uncovering nanostructures prior to gate structure formation, which reduces the risk of etch damage to the nanostructures or source/drain region. In some cases, the semiconductor material and/or the dummy dielectric material is not fully removed during formation of a mark structure, and the semiconductor material and/or dummy dielectric material remains in the completed mark structure. In some cases, gaps or voids may be formed when the dummy dielectric material is deposited, and the gaps or voids may remain in the completed mark structure.

In an embodiment of the present disclosure, a method includes forming a first nanostructure stack and a second nanostructure stack over a substrate, wherein the first nanostructure stack and the second nanostructure stack include alternating layers of a first semiconductor material and a second semiconductor material; performing a first etching process, wherein the first etching process removes the first semiconductor material of the first nanostructure stack to form first openings and recesses the first semiconductor material of the second nanostructure stack to form second openings; depositing a first dielectric material in the first openings and on the second semiconductor material in the second openings; performing a second etching process, wherein the second etching process removes the first dielectric material from the first openings, wherein the first dielectric material remains on the second semiconductor material in the second openings after performing the second etching process; and forming gate structures in the first openings. In an embodiment, the first semiconductor material is silicon germanium and the second semiconductor material is silicon. In an embodiment, the method includes etching a trench in the substrate, wherein the second nanostructure stack is formed in the trench. In an embodiment, the first dielectric material is oxide. In an embodiment, after depositing the first dielectric material, a gap separates a portion of the first dielectric material from a sidewall of the first semiconductor material in the second nanostructure stack. In an embodiment, the method includes forming an epitaxial source/drain region on the second semiconductor material of the first nanostructure stack. In an embodiment, the method includes depositing an inter-layer dielectric (ILD) layer over the second nanostructure stack. In an embodiment, the second nanostructure stack is part of a frame mark.

In an embodiment of the present disclosure, a method includes forming a fin over a substrate; forming first nanostructures and second nanostructures over the fin, wherein the first nanostructures extend between adjacent ones of the second nanostructures; replacing the first nanostructures with dielectric regions, wherein the dielectric regions extend between adjacent ones of the second nanostructures; etching the dielectric regions, wherein portions of the dielectric regions extend between adjacent ones of the second nanostructures after the etching; and forming a gate structure over the portions of the dielectric regions and over the second nanostructures. In an embodiment, after etching the dielectric regions, a gap separates a first dielectric region from a second dielectric region, wherein the first dielectric region and the second dielectric region extend between the same ones of the adjacent second nanostructures. In an embodiment, the method includes forming a dummy gate over the fin, the first nanostructures, and the second nanostructures. In an embodiment, a distance between the dummy gate and an end of the fin is greater than 100 nm. In an embodiment, replacing the first nanostructures with dielectric regions includes: etching the first nanostructures with an etchant that selectively etches the first nanostructures at a greater rate than the second nanostructures; and depositing a dielectric material on the second nanostructures. In an embodiment, the method includes forming a shallow trench isolation (STI) region surrounding the fin; and forming a hard mask on the STI region.

In an embodiment of the present disclosure, a device includes a substrate; a mark structure over the substrate, wherein the mark structure includes: alternating layers of a first semiconductor material and a second semiconductor material; first dielectric regions, wherein the first dielectric regions are adjacent respective sidewalls of the first semiconductor material; and second dielectric regions, wherein the second dielectric regions are adjacent respective sidewalls of the plurality of first dielectric regions; and nanostructures over the substrate, wherein the nanostructures are surrounded by a gate structure. In an embodiment, the first dielectric regions and the second dielectric regions are different dielectric materials. In an embodiment, the second dielectric regions and the layers of second semiconductor material have coterminous surfaces. In an embodiment, the first dielectric regions extend respectively between a second dielectric region and a layer of first semiconductor material. In an embodiment, the nanostructures include the second semiconductor material. In an embodiment, the first dielectric regions cover the adjacent respective sidewalls of the first semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first nanostructure stack and a second nanostructure stack over a substrate, wherein the first nanostructure stack and the second nanostructure stack comprise alternating layers of a first semiconductor material and a second semiconductor material;
performing a first etching process, wherein the first etching process removes the first semiconductor material of the first nanostructure stack to form first openings and recesses the first semiconductor material of the second nanostructure stack to form second openings;
depositing a first dielectric material in the first openings and on the second semiconductor material in the second openings;
performing a second etching process, wherein the second etching process removes the first dielectric material from the first openings, wherein the first dielectric material remains on the second semiconductor material in the second openings after performing the second etching process; and
forming gate structures in the first openings.

2. The method of claim 1, wherein the first semiconductor material is silicon germanium and the second semiconductor material is silicon.

3. The method of claim 1 further comprising etching a trench in the substrate, wherein the second nanostructure stack is formed in the trench.

4. The method of claim 1, wherein the first dielectric material is oxide.

5. The method of claim 1, wherein after depositing the first dielectric material, a gap separates a portion of the first dielectric material from a sidewall of the first semiconductor material in the second nanostructure stack.

6. The method of claim 1 further comprising forming an epitaxial source/drain region on the second semiconductor material of the first nanostructure stack.

7. The method of claim 1 further comprising depositing an inter-layer dielectric (ILD) layer over the second nanostructure stack.

8. The method of claim 1, wherein the second nanostructure stack is part of a frame mark.

9. A method comprising:
forming a fin over a substrate;
forming a plurality of first nanostructures and a plurality of second nanostructures over the fin, wherein the first nanostructures extend between adjacent ones of the second nanostructures;
replacing the plurality of first nanostructures with dielectric regions, wherein the dielectric regions extend between adjacent ones of the second nanostructures;
etching the dielectric regions, wherein portions of the dielectric regions extend between adjacent ones of the second nanostructures after the etching; and
forming a gate structure over the portions of the dielectric regions and over the second nanostructures.

10. The method of claim 9, wherein after etching the dielectric regions, a gap separates a first dielectric region from a second dielectric region, wherein the first dielectric region and the second dielectric region extend between the same ones of the adjacent second nanostructures.

11. The method of claim 9 further comprising forming a dummy gate over the fin, the plurality of first nanostructures, and the plurality of second nanostructures.

12. The method of claim 11, wherein a distance between the dummy gate and an end of the fin is greater than 100 nm.

13. The method of claim 12, wherein replacing the plurality of first nanostructures with dielectric regions comprises:
etching the first nanostructures with an etchant that selectively etches the first nanostructures at a greater rate than the second nanostructures; and
depositing a dielectric material on the second nanostructures.

14. The method of claim 9, further comprising:
forming a shallow trench isolation (STI) region surrounding the fin; and
forming a hard mask on the STI region.

15. A device comprising:
a substrate;
a mark structure over the substrate, wherein the mark structure comprises:
alternating layers of a first semiconductor material and a second semiconductor material;
a plurality of first dielectric regions, wherein the first dielectric regions are adjacent respective sidewalls of the first semiconductor material; and
a plurality of second dielectric regions, wherein the second dielectric regions are adjacent respective sidewalls of the plurality of first dielectric regions; and
a plurality of nanostructures over the substrate, wherein the nanostructures are surrounded by a gate structure.

16. The device of claim 15, wherein the first dielectric regions and the second dielectric regions comprise different dielectric materials.

17. The device of claim 15, wherein the plurality of second dielectric regions and the layers of second semiconductor material have coterminous surfaces.

18. The device of claim 15, wherein the first dielectric regions extend respectively between a second dielectric region and a layer of first semiconductor material.

19. The device of claim 15, wherein the nanostructures comprise the second semiconductor material.

20. The device of claim 15, wherein the first dielectric regions cover the adjacent respective sidewalls of the first semiconductor material.
